(19) United States
(12) Patent Application Publication
(10) Pub. No.: US 2012/0049187 A1
(43) Pub. Date: Mar. 1, 2012

(54) SEMICONDUCTOR DEVICE

(75) Inventors: Masamitsu HARUYAMA, Kanagawa (JP); Tatsuhiro Seki, Kanagawa (JP); Daisuke Arai, Kanagawa (JP)

(73) Assignee: RENESAS ELECTRONICS CORPORATION

(21) Appl. No.: 13/219,662

(22) Filed: Aug. 27, 2011

(30) Foreign Application Priority Data
Sep. 1, 2010 (JP) 2010-195410

(51) Int. Cl. H01L 27/07

(52) U.S. Cl. 257/49; 257/E27.033

(57) ABSTRACT

Accompanying the miniaturization of a gate electrode of a trench gate power MOSFET, the curvature of the bottom part of the trench increases, and thereby, electric fields concentrate on the part and deterioration of a gate oxide film (insulating film) occurs. The deterioration of the gate insulating film is more likely to occur when the gate side bias is negative in the case of an N-channel type power MOSFET and when the gate side bias is positive in the case of a P-channel type power MOSFET.

The present invention is a semiconductor device including an insulating gate power transistor etc. in a chip, wherein a gate protection element includes a bidirectional Zener diode and the bidirectional Zener diode has a plurality of P-type impurity regions (or a P-type impurity region) having different concentrations so that the withstand voltage with its gate side negatively biased and the withstand voltage with the gate side positively biased are different from each other.

### CROSS-REFERENCE TO RELATED APPLICATION

The disclosure of Japanese Patent Application N 2010-195410 filed on Sep. 1, 2010 including the specification, drawings and abstract is incorporated herein by reference in its entirety.

### BACKGROUND

The present invention relates to technology effective when applied to surge voltage protection technology in a semiconductor device (or semiconductor integrated circuit device).

Japanese Patent Laid-Open No. 1998-65157 (Patent Document 1) discloses technology to provide an N+PN+-type Zener protection element over a field oxide film in a P-channel type power MOSFET (Metal Oxide Semiconductor Field Effect Transistor).

Japanese Patent Laid-Open No. 2006-324570 (Patent Document 2) or United States Patent Application Publication No. 2009-230467 (Patent Document 3) corresponding to the former discloses technology to form a protection diode to prevent electrostatic breakdown of a gate insulating film and an embedded field plate in a polysilicon layer in the same layer in a power MISFET (Metal Insulator Semiconductor Field Effect Transistor) having an embedded field plate.

### SUMMARY

According to the examination of miniaturization of a trench gate power MOSFET made by the inventors of the present application, it has been made clear that accompanying the miniaturization of a gate electrode of a trench gate power MOSFET, the curvature of the bottom part of the trench increases and as a result of that, electric fields concentrate on the part and deterioration of a gate oxide film (insulating film) is caused by an FN (Fowler-Nordheim) tunnel current etc. In the case of an N-channel type power MOSFET, the deterioration of a gate insulating film is more likely to occur when the gate side bias is negative because a majority carrier is an electron.

On the other hand, in the case of a P-channel type power MOSFET, the deterioration is more likely to occur when the gate side bias is positive because a majority carrier is a hole.

The present invention has been made to solve these problems.

The present invention has been made in view of the above circumstances and provides a highly reliable manufacturing process of a semiconductor device.

The other purposes and the new feature of the present invention will become clear from the description of the present specification and the accompanying drawings.

The following explains briefly the outline of a typical invention among the inventions disclosed in the present application.

That is, an invention of the present application is a semiconductor device comprising an insulating gate power transistor and its gate protection element in a chip. The gate protection element includes a bidirectional Zener diode having a multistage PN junction and the bidirectional Zener diode has the withstand voltage with its gate side negatively biased and the withstand voltage with the gate side positively biased, different from each other. The bidirectional Zener diode has (1) a source side first conductivity type region, (2) a gate side first conductivity type region having substantially the same impurity concentration as that of the source side first conductivity type region and formed in a part nearer to the gate in a circuit, and (3) a second conductivity type region coupled in series between the source side first conductivity type region and the gate side first conductivity type region, forming a source side PN junction between the source side first conductivity type region and itself , and forming a gate side PN junction between the gate side first conductivity type region and itself. The second conductivity type region has concentrations different from each other in both end parts thereof .

The following explains briefly the effect acquired by the typical invention among the inventions disclosed in the present application.

That is, a semiconductor device comprises an insulating gate power transistor and its gate protection element in a chip and the gate protection element includes a bidirectional Zener diode having a multistage PN junction.

The bidirectional Zener diode has the withstand voltage with its gate side negatively biased and that with the gate side positively biased, different from each other. The bidirectional Zener diode has (1) a source side first conductivity type region, (2) a gate side first conductivity type region having substantially the same impurity concentration as that of the source side first conductivity type region and formed in a part nearer to the gate in a circuit, and (3) a second conductivity type region coupled in series between the source side first conductivity type region and the gate side first conductivity type region, forming a source side PN junction between the source side first conductivity type region and itself , and forming a gate side PN junction between the gate side first conductivity type region and itself. The second conductivity type region has concentrations differ from each other in both end parts thereof, and therefore, it is possible to effectively prevent deterioration caused by ESD (Electro-Static Discharge) of the gate insulating film.

### BRIEF DESCRIPTION OF THE DRAWINGS

FIG. 1 is a schematic top view of a device chip including a power MOSFET (insulating gate power transistor) and a gate protection element (one-dimensional multi-concentration type), which is an example of a semiconductor device in an embodiment of the present application;

FIG. 2 is a device schematic section view substantially corresponding to an A-B section (solid line part) in FIG. 1;

FIG. 3 is an enlarged top view of the gate protection element in FIG. 1;

FIG. 4 is a schematic section view, substantially corresponding to the A-B section (solid line part) in FIG. 1, of a device chip including a device structure (single gate structure) of a power MOSFET and a gate protection element (one-dimensional short circuit type), which is the example of the semiconductor device in the embodiment of the present application;

FIG. 5 is an enlarged top view of the gate protection element in FIG. 4;

FIG. 6 is a schematic section view, substantially corresponding to the A-B section (solid line part) in FIG. 1, of a device chip including a device structure (single gate structure) of a power MOSFET and a gate protection element (two-dimensional type), which is the example of the semiconductor device in the embodiment of the present application;

FIG. 7 is an enlarged top view of the gate protection element (two-dimensional multi-concentration type) in FIG. 6;

FIG. 8 is an enlarged top view of a modified example (two-dimensional short circuit type) of the gate protection element in FIG. 6;

FIG. 9 is a device section view in each wafer process step (epitaxial wafer provision step) corresponding to FIG. 2 of the device chip including the power MOSFET (insulating gate power transistor) and the gate protection element (one-dimensional multi-concentration type), which is the example of the semiconductor device in the embodiment of the present application;

FIG. 10 is a device section view in each wafer process step (well introduction and LOCOS silicon oxide film formation step) corresponding to FIG. 2 of the device chip including the power MOSFET (insulating gate power transistor) and the gate protection element (one-dimensional multi-concentration type), which is the example of the semiconductor device in the embodiment of the present application;

FIG. 11 is a device section view in each wafer process step (trench formation step) corresponding to FIG. 2 of the device chip including the power MOSFET (insulating gate power transistor) and the gate protection element (one-dimensional multi-concentration type), which is the example of the semiconductor device in the embodiment of the present application;

FIG. 12 is a device section view in each wafer process step (gate oxide film formation and doped polysilicon film deposition step) corresponding to FIG. 2 of the device chip including the power MOSFET (insulating gate power transistor) and the gate protection element (one-dimensional multi-concentration type), which is the example of the semiconductor device in the embodiment of the present application;

FIG. 13 is a device section view in each wafer process step (gate processing step) corresponding to FIG. 2 of the device chip including the power MOSFET (insulating gate power transistor) and the gate protection element (one-dimensional multi-concentration type), which is the example of the semiconductor device in the embodiment of the present application;

FIG. 14 is a device section view in each wafer process step (undoped polysilicon film deposition, processing, and boron ion injection step) corresponding to FIG. 2 of the device chip including the power MOSFET (insulating gate power transistor) and the gate protection element (one-dimensional multi-concentration type), which is the example of the semiconductor device in the embodiment of the present application;

FIG. 15 is a device section view in each wafer process step (step of injecting arsenic ions into source, channel stop, ESD protection Zener diode, etc.) corresponding to FIG. 2 of the device chip including the power MOSFET (insulating gate power transistor) and the gate protection element (one-dimensional multi-concentration type), which is the example of the semiconductor device in the embodiment of the present application;

FIG. 16 is a device section view in each wafer process step (step of additionally injecting boron. ions into ESD protection Zener diode etc.) corresponding to FIG. 2 of the device chip including the power MOSFET (insulating gate power transistor) and the gate protection element (one-dimensional multi-concentration type), which is the example of the semiconductor device in the embodiment of the present application;

FIG. 17 is a device section view in each wafer process step (interlayer insulating film deposition and contact hole etc. opening step) corresponding to FIG. 2 of the device chip including the power MOSFET (insulating gate power transistor) and the gate protection element (one-dimensional multi-concentration type), which is the example of the semiconductor device in the embodiment of the present application;

FIG. 18 is a device section view in each wafer process step (step of extending contact hole etc. and injecting boron etc. ions into body contact region) corresponding to FIG. 2 of the device chip including the power MOSFET (insulating gate power transistor) and the gate protection element (one-dimensional multi-concentration type), which is the example of the semiconductor device in the embodiment of the present application;

FIG. 19 is a device section view in each wafer process step (surface metal deposition, processing, back grinding, and back surface metal deposition step) corresponding to FIG. 2 of the device chip including the power MOSFET (insulating gate power transistor) and the gate protection element (one-dimensional multi-concentration type), which is the example of the semiconductor device in the embodiment of the present application;

FIG. 20 is a device section view in each wafer process step (epitaxial wafer provision step) of the device chip including a modified example (double gate structure) of the device structure of the power MOSFET (insulating gate power transistor) and the gate protection element (one-dimensional multi-concentration type), which is the example of the semiconductor device in the embodiment of the present application;

FIG. 21 is a device section view in each wafer process step (well introduction and LOCOS insulating film formation step) of the device chip including the modified example (double gate structure) of the device structure of the power MOSFET (insulating gate power transistor) and the gate protection element (one-dimensional multi-concentration type), which is the example of the semiconductor device in the embodiment of the present application;

FIG. 22 is a device section view in each wafer process step (trench formation step) of the device chip including the modified example (double gate structure) of the device structure of the power MOSFET (insulating gate power transistor) and the gate protection element (one-dimensional multi-concentration type), which is the example of the semiconductor device in the embodiment of the present application;

FIG. 23 is a device section view in each wafer process step (Resurf gate insulating film formation and Resurf undoped polysilicon film deposition step) of the device chip including the modified example (double gate structure) of the device structure of the power MOSFET (insulating gate power transistor) and the gate protection element (one-dimensional multi-concentration type), which is the example of the semiconductor device in the embodiment of the present application;

FIG. 24 is a device section view in each wafer process step (step of injecting P-type impurity ions into entire surface and selectively injecting N-type impurity ions) of the device chip including the modified example (double gate structure) of the device structure of the power MOSFET (insulating gate power transistor) and the gate protection element (one-dimensional multi-concentration type), which is the example of the semiconductor device in the embodiment of the present application;

FIG. 25 is a device section view in each wafer process step (first layer polysilicon film processing step) of the device chip including the modified example (double gate structure) of the device structure of the power MOSFET (insulating gate power transistor) and the gate protection element (one-dimensional multi-concentration type), which is the example of the semiconductor device in the embodiment of the present application;

FIG. 26 is a device section view in each wafer process step (Resurf gate insulating film etch back step) of the device chip including the modified example (double gate structure) of the device structure of the power MOSFET (insulating gate power transistor) and the gate protection element (one-dimensional multi-concentration type), which is the example of the semiconductor device in the embodiment of the present application;

FIG. 27 is a device section view in each wafer process step (intrinsic gate insulating film formation and intrinsic gate doped polysilicon film deposition step) of the device chip including the modified example (double gate structure) of the device structure of the power MOSFET (insulating gate power transistor) and the gate protection element (one-dimensional multi-concentration type), which is the example of the semiconductor device in the embodiment of the present application;

FIG. 28 is a device section view in each wafer process step (intrinsic gate doped polysilicon film deposition and processing step) of the device chip including the modified example (double gate structure) of the device structure of the power MOSFET (insulating gate power transistor) and the gate protection element (one-dimensional multi-concentration type), which is the example of the semiconductor device in the embodiment of the present application;

FIG. 29 is a device section view in each wafer process step (step of injecting boron ions into P body region, that is, channel region) of the device chip including the modified example (double gate structure) of the device structure of the power MOSFET (insulating gate power transistor) and the gate protection element (one-dimensional multi-concentration type), which is the example of the semiconductor device in the embodiment of the present application;

FIG. 30 is a device section view in each wafer process step (step of injecting arsenic ions into source, channel stop, ESD protection Zener diode, etc.) of the device chip including the modified example (double gate structure) of the device structure of the power MOSFET (insulating gate power transistor) and the gate protection element (one-dimensional multi-concentration type), which is the example of the semiconductor device in the embodiment of the present application;

FIG. 31 is a device section view in each wafer process step (step of additionally injecting boron ions into ESD protection Zener diode etc.) of the device chip including the modified example (double gate structure) of the device structure of the power MOSFET (insulating gate power transistor) and the gate protection element (one-dimensional multi-concentration type), which is the example of the semiconductor device in the embodiment of the present application;

FIG. 32 is a device section view in each wafer process step (interlayer insulating film deposition and contact hole etc. opening step) of the device chip including the modified example (double gate structure) of the device structure of the power MOSFET (insulating gate power transistor) and the gate protection element (one-dimensional multi-concentration type), which is the example of the semiconductor device in the embodiment of the present application;

FIG. 33 is a device section view in each wafer process step (step of extending contact hole etc. and injecting boron etc. ions into body contact region) of the device chip including the modified example (double gate structure) of the device structure of the power MOSFET (insulating gate power transistor) and the gate protection element (one-dimensional multi-concentration type), which is the example of the semiconductor device in the embodiment of the present application;

FIG. 34 is a device section view in each wafer process step (surface metal deposition, processing, back grinding, and back surface metal deposition step) of the device chip including the modified example (double gate structure) of the device structure of the power MOSFET (insulating gate power transistor) and the gate protection element (one-dimensional multi-concentration type), which is the example of the semiconductor device in the embodiment of the present application;

FIG. 35 is a device schematic section view of a device chip including a device structure of an IGBT, which is another example of the insulating gate power transistor corresponding to FIG. 2 in the semiconductor device in the embodiment of the present application, and a gate protection element (one-dimensional multi-concentration type);

FIG. 36 is a schematic section view of a gate protection Zener diode etc. for explaining a non-geometrically modified example (N-channel transistor both end N region & multi-concentration type) of a gate protection element in a device structure etc. (for example, FIG. 2, FIG. 34, and FIG. 35) of a power MOSFET, which is one of various examples of the semiconductor device in the embodiment of the present application;

FIG. 37 is a schematic section view of a gate protection Zener diode etc. for explaining a non-geometrically modified example (N-channel transistor both end P region & multi-concentration type) of a gate protection element in a device structure etc. (for example, FIG. 2, FIG. 34, and FIG. 35) of a power MOSFET, which is one of various examples of the semiconductor device in the embodiment of the present application;

FIG. 38 is a schematic section view of a gate protection Zener diode etc. for explaining a non-geometrically modified example (P-channel transistor both end N region & multi-concentration type) of a gate protection element in a device structure etc. (for example, FIG. 2, FIG. 34, and FIG. 35) of a power MOSFET, which is one of various examples of the semiconductor device in the embodiment of the present application;

FIG. 39 is a schematic section view of a gate protection Zener diode etc. for explaining a non-geometrically modified example (P-channel transistor both end P region & multi-concentration type) of a gate protection element in a device structure etc. (for example, FIG. 2, FIG. 34, and FIG. 35) of a power MOSFET, which is one of various examples of the semiconductor device in the embodiment of the present application;

FIG. 40 is a schematic section view of a gate protection Zener diode etc. for explaining a non-geometrically modified example (N-channel transistor ohmic coupling type) of a gate protection element in a device structure etc. (for example, FIG. 2, FIG. 34, and FIG. 35) of a power MOSFET, which is one of various examples of the semiconductor device in the embodiment of the present application;

FIG. 41 is a schematic section view of a gate protection Zener diode etc. for explaining a non-geometrically modified example (P-channel transistor ohmic coupling type) of a gate protection element in a device structure etc. (for example, FIG. 2, FIG. 34, and FIG. 35) of a power MOSFET, which is one of various examples of the semiconductor device in the embodiment of the present application;

FIG. 42 is a schematic section view of a gate protection Zener diode etc. for explaining a non-geometrically modified example (N-channel transistor both end N region & short circuit type) of a gate protection element in a device structure etc. (for example, FIG. 2, FIG. 34, and FIG. 35) of a power MOSFET, which is one of various examples of the semiconductor device in the embodiment of the present application; and

FIG. 43 is a schematic section view of a gate protection Zener diode etc. for explaining a non-geometrically modified example (P-channel transistor short circuit type) of a gate protection element in a device structure etc. (for example, FIG. 2, FIG. 34, and FIG. 35) of a power MOSFET, which is one of various examples of the semiconductor device in the embodiment of the present application.

### DETAILED DESCRIPTION

### Outline of Embodiments

First, the outline of typical embodiments of the inventions disclosed in the present application is explained.

1. A semiconductor device, comprising:

(a) a semiconductor chip;

(b) an insulating gate power transistor formed on the semiconductor chip; and

(c) a gate protection element formed in the semiconductor chip and coupled between a gate terminal and a source terminal of the insulating gate power transistor,

the gate protection element including a bidirectional Zener diode having a multistage PN junction,

wherein the bidirectional Zener diode has

the withstand voltage with its gate terminal side negatively biased and the withstand voltage with the gate terminal side positively biased, different from each other, and wherein the bidirectional Zener diode includes: (x1) a source side first conductivity type region; (x2) a gate side first conductivity type region having substantially the same impurity concentration as that of the source side first conductivity type region and formed in a part nearer to the gate terminal in a circuit; and (x3) a second conductivity type region coupled in series between the source side first conductivity type region and the gate side first conductivity type region, forming a source side PN junction between the source side first conductivity type region and itself, and forming a gate side PN junction between the gate side first conductivity type region and itself, the second conductivity type region having concentrations different from each other in both end parts thereof.

2. In the semiconductor device according to the item 1 described above, when the insulating gate power transistor is an N-channel type, the bidirectional Zener diode has the withstand voltage with its gate terminal side negatively biased set lower compared to that with the gate terminal side positively biased, and when the insulating gate power transistor is a P-channel type, the bidirectional Zener diode has the withstand voltage with the gate terminal side positively biased set lower compared to that with the gate terminal side negatively biased.

3. In the semiconductor device according to the item 1 or 2 described above, a piece of polysilicon film comprises the bidirectional Zener diode.

4. In the semiconductor device according to the item 3 described above, the polysilicon film constituting the bidirectional Zener diode is formed in a layer different from the layer in which a polysilicon film constituting polysilicon intrinsic gate electrode of the insulating gate power transistor is formed.

5. In the semiconductor device according to any one of the items 1 to 4 described above, both end parts of the bidirectional Zener diode are N-type regions.

6. In the semiconductor device according to any one of the items 1 to 5 described above, the bidirectional Zener diode is a one-dimensional type.

7. In the semiconductor device according to any one of the items 1 to 5 described above, the bidirectional Zener diode is a two-dimensional type and each region constituting the bidirectional Zener diode has a rounded planar. shape.

8. In the semiconductor device according to any one of the items 1 to 7 described above, the second conductivity type region includes two regions having different concentrations.

9. In the semiconductor device according to any one of the items 1 to 8 described above, the insulating gate power transistor is an insulating gate power MOSFET.

10. In the semiconductor device according to any one of the items 1 to 8 described above, the insulating gate power transistor is an IGBT.

11. A semiconductor device comprising: (a) a semiconductor chip; (b) an insulating gate power transistor formed in the semiconductor chip; and (c) a gate protection element formed in the semiconductor chip and coupled between a gate and a source of the insulating gate power transistor, the gate protection element having the withstand voltage with its gate side negatively biased and the withstand voltage with the gate side positively biased, different from each other, the gate protection element including: (x1) a bidirectional Zener diode having a multistage PN junction; and (x2) another Zener diode coupled in series between the gate and the source with an ohmic wiring together with the bidirectional Zener diode.

12. In the semiconductor device according to the item 11 described above, when the insulating gate power transistor is an N-channel type, the gate protection element has the withstand voltage with its gate terminal side negatively biased set lower compared to that with the gate terminal side positively biased, and when the insulating gate power transistor is a P-channel type, the gate protection element has the withstand voltage with its gate terminal side positively biased set lower compared to that with the gate terminal side negatively biased.

13. In the semiconductor device according to the item 11 or 12 described above, the regions of the bidirectional Zener diode and the another Zener diode interconnected to each other with the ohmic wiring are separated from each other.

14. In the semiconductor device according to the item 11 or 12 described above, the regions of the bidirectional Zener diode and the another Zener diode interconnected to each other with the ohmic wiring are coupled to each other to form a PN junction.

15. In the semiconductor device according to any one of the items 11 to 14 described above, the bidirectional Zener diode and the other Zener diode each are formed in the same single layer polysilicon film.

16. In the semiconductor device according to any one of the items 11 to 15 described above, the polysilicon film constituting the bidirectional Zener diode and the another Zener diode is formed in a layer different from the layer in which a polysilicon film constituting a polysilicon intrinsic gate electrode of the insulating gate power transistor is formed.

17. In the semiconductor device according to any one of the items 11 to 16 described above, the bidirectional Zener diode is a one-dimensional type.

18. In the semiconductor device according to any one of the items 11 to 16 described above, the bidirectional Zener diode is a two-dimensional type and each region constituting the bidirectional Zener diode has a rounded planar shape.

19. In the semiconductor device according to any one of the items 11 to 18 described above, the insulating gate power transistor is an insulating gate power MOSFET.

20. In the semiconductor device according to any one of the items 11 to 18 described above, the insulating gate power transistor is an IGBT.

21. In the semiconductor device according to any one of the items 14 to 20 described above, both end parts of the gate protection element are N-type regions.

[Explanation of Description Form, Basic Terms, and how to Use in the Present Application]

1. In the present application, there is a case where embodiments are described, divided into plural sections for convenience, if necessary, however, except for the case where it is clearly specified not in particular, they are not independent of each other but each part, one of a single example is a modification etc. of a partial detail, some or entire of another. As a principle, the repetition of the same part is omitted. Further, each component in the embodiments is not necessarily indispensable except for the case where it is clearly specified not in particular, where it is clearly restricted to a specific number theoretically, and where it is clearly not from context.

Further, a “transistor”, “semiconductor device”, or “semiconductor integrated circuit device” in the present application refers to a single transistor (active device) of various kinds of transistor and one in which resistors, capacitors, etc., with the transistor as a central component, are integrated on a semiconductor chip etc. (for example, single crystal silicon substrate). Here, as a typical transistor among the various kinds of transistor, mention is made, for example, of a MISFET (Metal Insulator Semiconductor Field Effect Transistor) represented by a MOSFET (Metal Oxide Semiconductor Field Effect Transistor). In the present application, it is assumed that a “MOSFET” includes not only one in which a gate insulating film is an oxide film but also one in which another insulating film is used as a gate insulating film.

2. Similarly, in the description of the embodiments etc., the wording “X including A” as to a material, composition, etc., does not exclude one which has an element other than A as one of its main components except for the case where it is clearly specified not in particular or the case where it is clearly not from context. For example, it means “X including A as a principal component” as to a component. For example, a “silicon member” etc. is not limited to pure silicon and it is needless to say that a SiGe alloy, a multi-element alloy containing silicon as a principal component, members including other additives, etc., are also included. Similarly, it is needless to say that “silicon oxide film”, “silicon oxide-based insulating film”, etc., also include, in addition to a comparatively pure undoped silicon dioxide, FSG (Fluorosilicate Glass), TEOS-based silicon oxide, SiOC (Silicon Oxicarbide) or carbon-doped silicon oxide or OSG (Organosilicate glass), a thermally oxidized film, such as PSG (Phosphorus Silicate Glass) and BPSG (Borophosphosilicate Glass), a CVD oxide film, SOG (Spin On Glass), silicon oxide for application, such as nano-clustering silica (NCS), a silica-based Low-k insulating film (porous insulating film) in which cavities are introduced into the same members as those described above, a compound film with another silicon-based insulating film containing these as a principal component, etc.

3. Similarly, appropriate examples of figures, positions, attributes, etc., are shown, however, it is needless to say that these are not limited strictly except for the case where it is clearly specified not in particular and where it is clearly not from context.

4. Further, when referring to a specific value, the number of elements, except for the case where they are clearly specified not in particular, where they are clearly restricted to the specific value, number theoretically, and where they are clearly not from context, they may be greater or smaller than the specific value, number.

5. When referring to a “wafer”, usually, it refers to a single crystal silicon wafer over which a semiconductor device (semiconductor integrated circuit device, electronic device are also included) is formed, however, it is needless to say that it includes a compound wafer etc. of an insulating substrate, such as an epitaxial wafer, an SOI substrate, and an LCD glass substrate, and a semiconductor layer etc.

6. In the present application, a “power semiconductor” refers to a semiconductor device capable of handling an electric power of several watts or more. Among the power semiconductors, the power MOSFET, power IGBT (Insulated gate Bipolar Transistor), etc., belong to the category of the “insulating gate power transistor”. Consequently, all of the normal power MOSFETs are included in this category.

Among the power MOSFETs, one having a structure in which the surface serves as a source and the back surface serves as a drain is referred to as a vertical power MOSFET.

Among the vertical power MOSFETs, a “trench gate power MOSFET” refers to one in which, normally, there is a gate electrode including polysilicon etc. within a trench (comparatively long, narrow groove) formed on the device surface (first main surface) of a semiconductor substrate and a channel is formed in the direction of thickness of the semiconductor substrate. In this case, normally, the device surface side of the semiconductor substrate serves as a source and the back surface side (second main surface side) serves as a drain. A part of the essential part (part other than the electrode drawing part) of the gate electrode may bulge out of the trench.

Among the trench gate power MOSFETs, an “in-trench double gate power MOSFET” refers to one having a Resurf gate, that is, a (embedded) field plate electrode under the gate electrode (intrinsic gate electrode) within the trench. Because of the problem of manufacturing, there are a number of cases where the gate electrode (intrinsic gate electrode) and the field plate electrode (field plate gate electrode) are separated within the trench (double gate isolation type structure), however, one having a structure in which the gate electrode and the field plate electrode are integrated is also deemed to belong to the in-trench double gate power MOSFET. The double gate isolation structure is further classified into a “gate coupling type” in which the potential of. the field plate gate electrode is made the same as that of the intrinsic gate electrode (the field plate gate electrode is coupled to the intrinsic gate electrode outside the trench) and a “source coupling type” in which the potential of the field plate gate electrode is made the same as that of the source electrode (the field plate gate electrode is coupled to the source electrode outside the trench).

Here, the “field plate electrode” refers to an electrode that has a function to disperse a steep potential gradient concentrating on the part in the vicinity of the drain side end part of the gate electrode and normally, which is electrically coupled to the source electrode or the gate electrode. Normally, the boundary surface between the field plate electrode and the drift region is configured by an insulating film thicker than the gate insulting film (intrinsic gate insulating film).

In the present application, the normal power trench MOSFET that does not have an embedded field plate electrode (Resurf gate) is referred to as a “single gate trench MOSFET”.

The IGBT is a vertical power MOSFET in which a collector layer of conductivity type different from that of the drain region is attached to the drain side and the source of the vertical power MOSFET, which is one of the components, is referred to as an “emitter” practically, however, in the present application, except for the case where it is necessary to call it an “emitter”, the original name of the vertical power MOSFET, that is, a “source” is used and it is called a “source”, “source region”, “source electrode”, etc.

### Details of Embodiments

The embodiments are described in more detail. In each of the drawings, the same or similar part is represented by the same or similar symbol or reference numeral and, as a principle, its explanation is not repeated.

In the attached drawing, when it becomes complicated or it can be clearly distinguished from a vacant space, hatching may be omitted even if it is a section view. In relation to this, the background contour line may be omitted when it is obvious from explanation etc. even if it is a closed hole in a plane. Further, hatching may be attached to explicitly indicate that the part is not a vacant space even if it is not a section view.

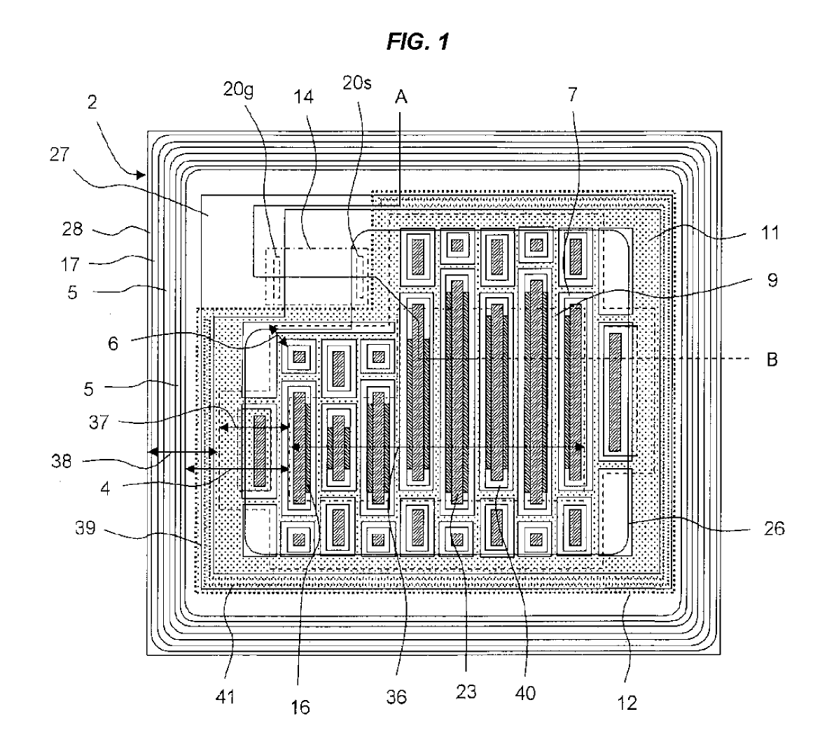

1. Explanation of a Device Structure of a Power MOSFET (Insulating Gate Power Transistor) and a Gate Protection Element (One-Dimensional Multi-Concentration Type), which is an Example of a Semiconductor Device in an Embodiment of the Present Application (Mainly from FIG. 1 to FIG. 3)

In this section, a device structure is explained specifically by taking a single gate trench MOSFET as an example. In a plan view particularly, in order to explain a relationship between a cell region and its peripheral region, the number of trenches is much reduced compared to the actual number (the actual number of trenches is about several hundreds to several thousands). Further, in order to explain a buffer region, the area of the buffer region is shown much increased compared to the area of the cell region.

As to the in-trench double gate power MOSFET (see the section 6) also, its planar layout is basically the same as that of the single gate trench MOSFET, and therefore, its different parts are explained in the section view.

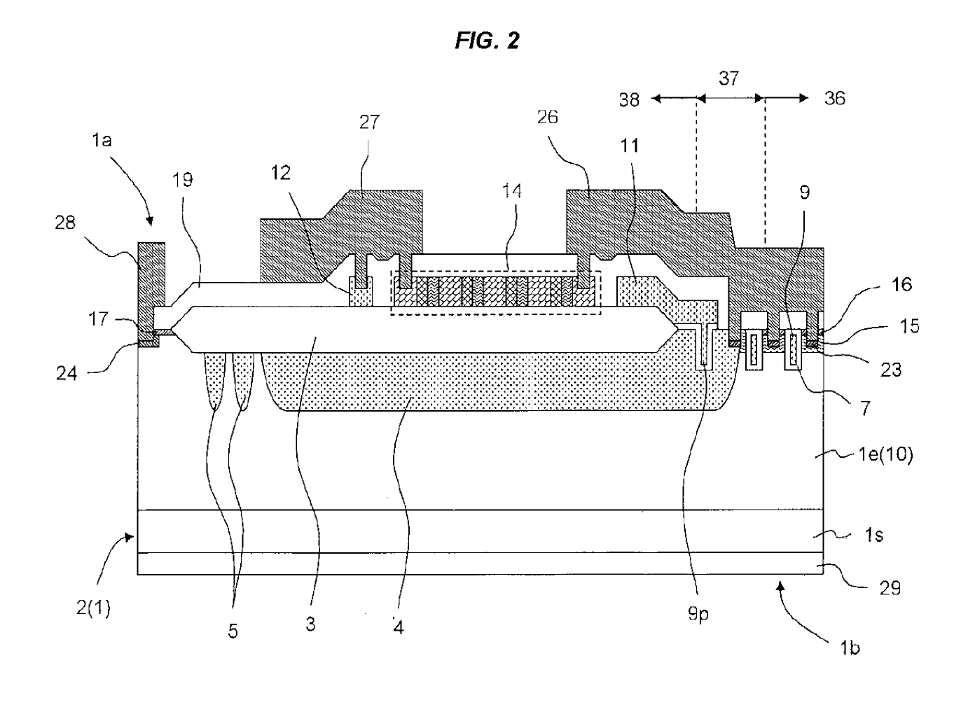

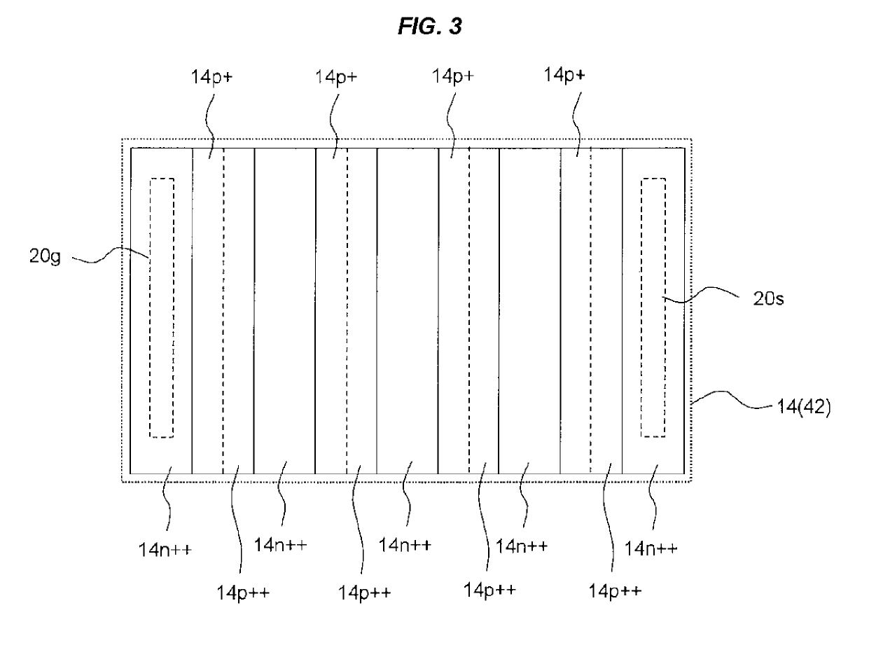

FIG. 1 is a schematic top view of a device chip including a power MOSFET (insulating gate power transistor) and a gate protection element (one-dimensional multi-concentration type), which is an example of a semiconductor device in an embodiment of the present application. FIG. 2 is a device schematic section view substantially corresponding to an A-B section (solid line part) in FIG. 1. FIG. 3 is an enlarged top view of the gate protection element in FIG. 1. Based on these, a device structure of a power MOSFET (insulating gate power transistor) and a gate protection element (one-dimensional multi-concentration type), which is the example of the semiconductor device in the embodiment of the present application, are explained.

First, the chip planar layout (chip top surface layout) of a trench MOSFET in which a gate protection element 14 is incorporated is explained based on FIG. 1 (see FIG. 2 appropriately). As shown in FIG. 1, on the outermost circumference of a surface 1a of a semiconductor chip 2 (semiconductor substrate 1), there is an annular metal guard ring 28 (for example, an aluminum-based metal guard ring etc.) and inside thereof, there is an annular N-type channel stop region 17 (region introduced at the same time as an N-type source region 16). Further, inside thereof, one, two, or more field limiting rings 5 or floating field rings are provided and at the chip center part inside the field limiting ring 5, a cell region 36 is provided. A P well region 4 in the form of a somewhat complicated annulus is embedded between the field limiting ring 5 and the cell region 36 and the peripheral part of the cell region 36 is a buffer region 37 having a structure different from that of the inner region. The outside thereof is a chip peripheral region 38 with the buffer region 37 sandwiched in between.

The cell region 36 and the buffer region 37 are provided with trenches 6 in the form of a mesh and a trench gate electrode in the form of a comparatively thin slab, that is, a polysilicon gate electrode 9 (for example, a first layer polysilicon film 8) is embedded therein via a gate insulating film 7. The polysilicon gate electrode 9 is extracted outside the trench 6 by a first layer polysilicon extraction unit 11 and coupled to a metal gate wiring 39 at the part of a first layer polysilicon wiring 12 on the periphery via a metal & polysilicon coupling hole 41 and reaches a metal gate electrode 27 (gate pad).

In the cell region 36, in an active region 40 (part other than the trench in the cell region) between the trenches 6 in the form of a mesh, a P-type body contact region 23 is provided and on the periphery thereof, the N-type source region 16 (also called an emitter region in the case of IGBT) is provided. To the P-type body contact region 23, a metal source electrode 26 (source pad) is coupled and the gate protection element 14 is coupled to the metal gate electrode 27 (gate terminal) via a gate side contact part 20g and to the metal source electrode 26 (source terminal) via a source side contact part 20s.

Next, a basic sectional structure is explained based on FIG. 2. As shown in FIG. 2, a semiconductor substrate, that is, a substrate layer is, for example, a single crystal N-type silicon substrate having a comparatively high concentration and on its back surface 1b, a drain metal electrode 29 is provided. On the surface of the substrate layer is, an N-type silicon epitaxy layer 1e (drift region 10) having a comparatively low concentration is provided and in the chip peripheral region 38 in the surface region of the N-type silicon epitaxy layer 1e, the P well regions 4, 5 and a P-type peripheral contact region 24 (for example, formed at the same time as the P-type body contact region 23) are provided. On the other hand, across the entire surface and the periphery of the cell region 36 in the surface region of the N-type silicon epitaxy layer 1e, a P body region 15 (P-type body region) constituting a channel region is formed. Over the surface of the N-type silicon epitaxy layer 1e of the chip peripheral region 38, a field insulating film 3 is formed and an interlayer insulating film 19 is formed thereover. Within the trench in the buffer region 37, a peripheral dummy polysilicon gate electrode 9p is provided and prevents deterioration in withstand voltage on the periphery of the cell region 36.

Next, based on FIG. 3 (see FIG. 1 and FIG. 2), an example of a detailed structure of the gate protection element 14 (protection diode, electrostatic protection element, surge protection element) shown in FIG. 1 and FIG. 2 is explained. As shown in FIG. 3, the gate protection element 14 is, for example, an integrated bidirectional Zener diode 42 formed by a second layer polysilicon film, in which, an N-type high concentration region 14n++, a P-type intermediate concentration region 14p+, and a P-type high concentration region 14p++ each having a cylindrical shape are linked repeatedly in a circulating manner from the side of the gate side contact part 20g and the last one is the N-type high concentration region 14n++, forming the source side contact part 20s. Consequently, in FIG. 1 and FIG. 2, the withstand voltage of the bidirectional Zener diode 42 when the metal gate electrode 27 (gate terminal) is negatively biased compared to the metal source electrode 26 (source terminal) is considerably lower than the withstand voltage when a backward voltage is applied. As described above, the withstand voltage characteristics of the gate protection element 14 are asymmetric with respect to the direction of the applied bias, and therefore, it is possible to effectively prevent the deterioration caused by ESD of the gate insulating film.

Both ends of the bidirectional Zener diode 42 are the N-type high concentration regions, and therefore, there is an advantage that the contact resistance with the aluminum-based metal electrodes 26, 27 can be reduced. This also applies to the various examples below in which both ends are the N-type high concentration regions.

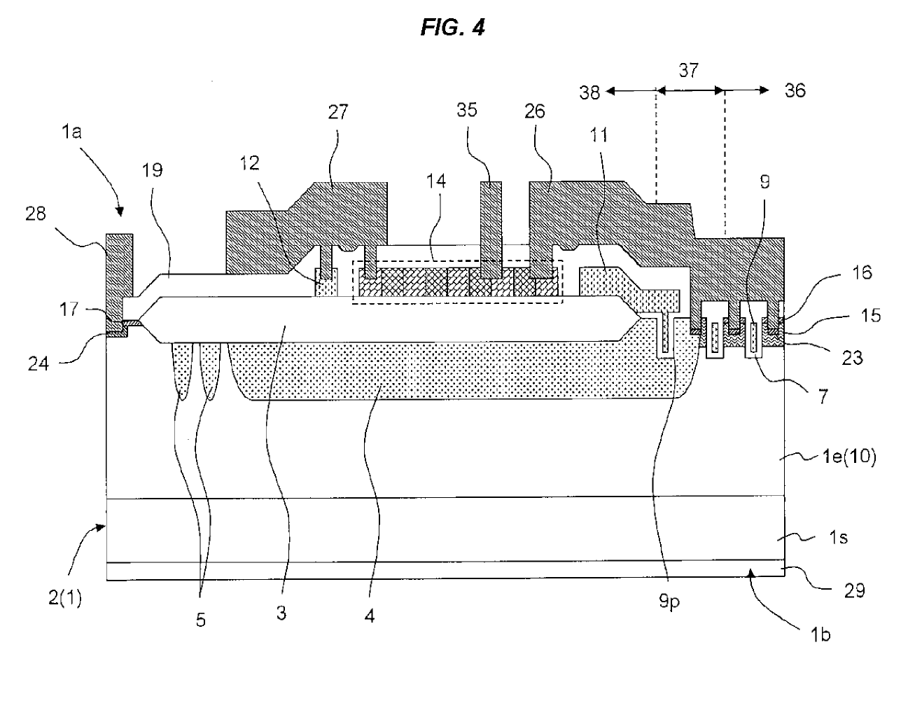

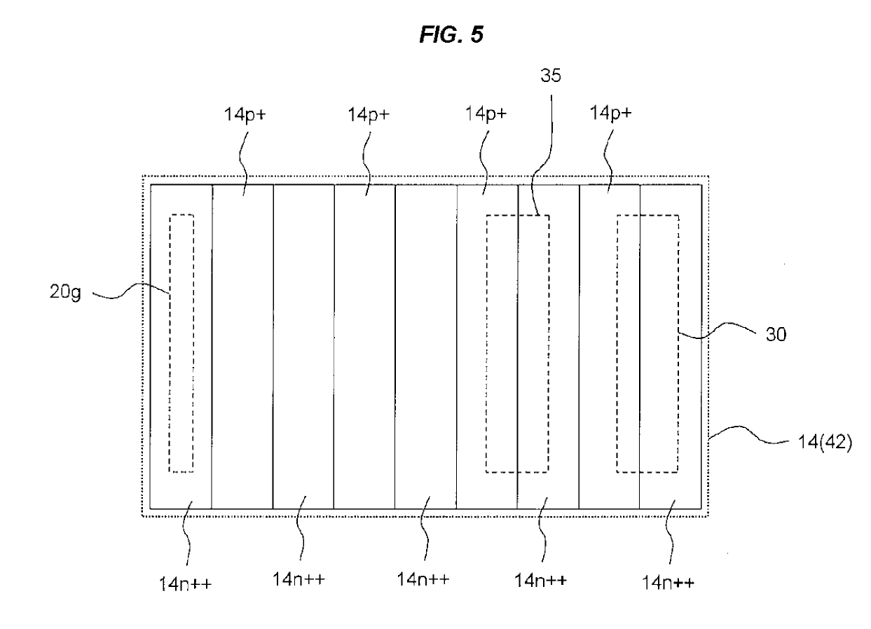

2. Explanation of a Geometrically Modified Example 1 (One-Dimensional Short Circuit Type) of the Gate Protection Element in the Device Structure (Single Gate Structure) etc. of the Power MOSFET, which is the Example of the Semiconductor Device in the Embodiment of the Present Application (Mainly FIG. 4 and FIG. 5)

In this section, a modified example of the gate protection element 14 etc. explained in the section 1 is explained.

FIG. 4 is a schematic section view, substantially corresponding to the A-B section (solid line part) in FIG. 1, of a device chip including a device structure (single gate structure) of a power MOSFET and a gate protection element (one-dimensional short circuit type), which is the example of the semiconductor device in the embodiment of the present application. FIG. 5 is an enlarged top view of the gate protection element in FIG. 4. Based on these, the geometrically modified example 1 (one-dimensional short circuit type) of the gate protection element in the device structure (single gate structure) etc. of the power MOSFET, which is the example of the semiconductor device in the embodiment of the present application, is explained.

As shown in FIG. 4 and FIG. 5, the gate protection element 14 is, as in the section 1, the integrated bidirectional Zener diode 42 formed by the second layer polysilicon film, in which the N-type high concentration region 14n++ and the P-type intermediate concentration region 14p+ each having a cylindrical shape are linked repeatedly in a circulating manner from the side of the gate side contact part 20g and the last one is the N-type high concentration region 14n++, forming the source side contact part 20s. In this state, the withstand voltage characteristics of the gate protection element 14 are symmetric with respect to the direction of the applied bias, and therefore, for example, as shown in FIG. 4 and FIG. 5, the withstand voltage characteristics are caused to be asymmetric by short-circuiting the N-type high concentration region 14n++ and the P-type intermediate concentration region 14p+ adjacent to each other at the source side contact, a short circuit part 30, and a short circuit part 35 by making use of a part of the aluminum-based wiring etc. Because of this, the withstand voltage of the bidirectional Zener diode 42 when the metal gate electrode 27 (gate terminal) is negatively biased compared to the metal source electrode 26 (source terminal) is considerably lower than the withstand voltage when a backward voltage is applied. As described above, the withstand voltage characteristics of the gate protection element 14 are asymmetric with respect to the direction of the applied bias, and therefore, it is possible to effectively prevent the deterioration caused by ESD of the gate insulating film.

In FIG. 4, FIG. 5, the parts of the diffusion layers of the N-type high concentration region 14n++ and the P-type intermediate concentration region 14p+ coupled to the short circuit part 35 are joined, however, these joined parts may be separated.

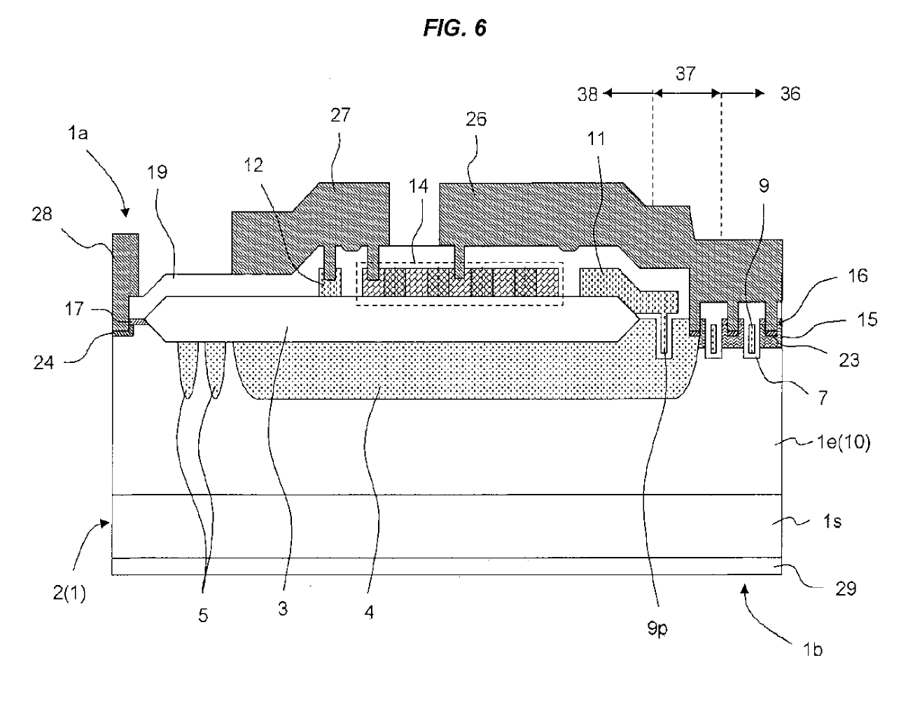

3. Explanation of a Geometrically Modified Example 2 (Two-Dimensional Type) of the Gate Protection Element in the Device Structure etc. of the Power MOSFET, which is the Example of the Semiconductor Device in the Embodiment of the Present Application (Mainly from FIG. 6 to FIG. 8)

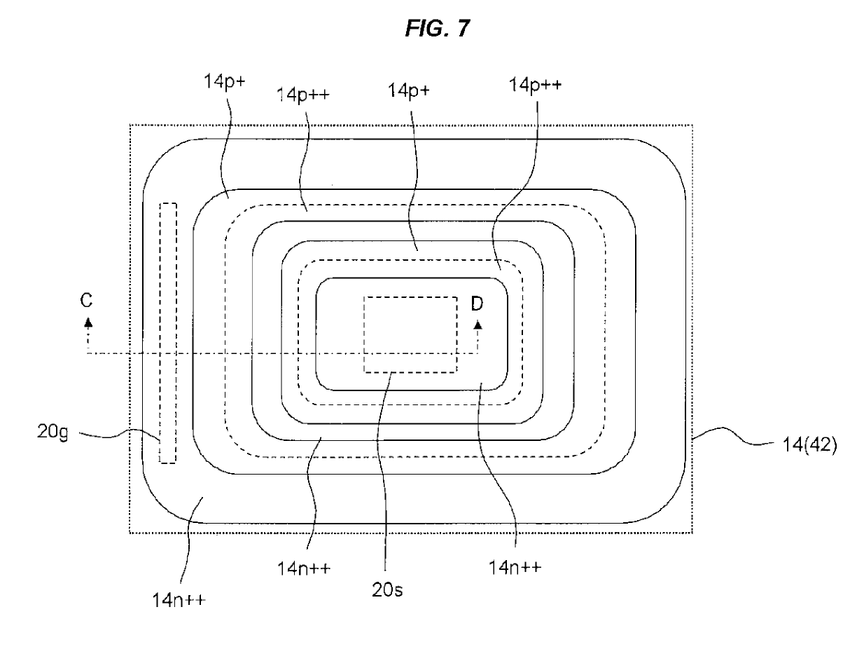

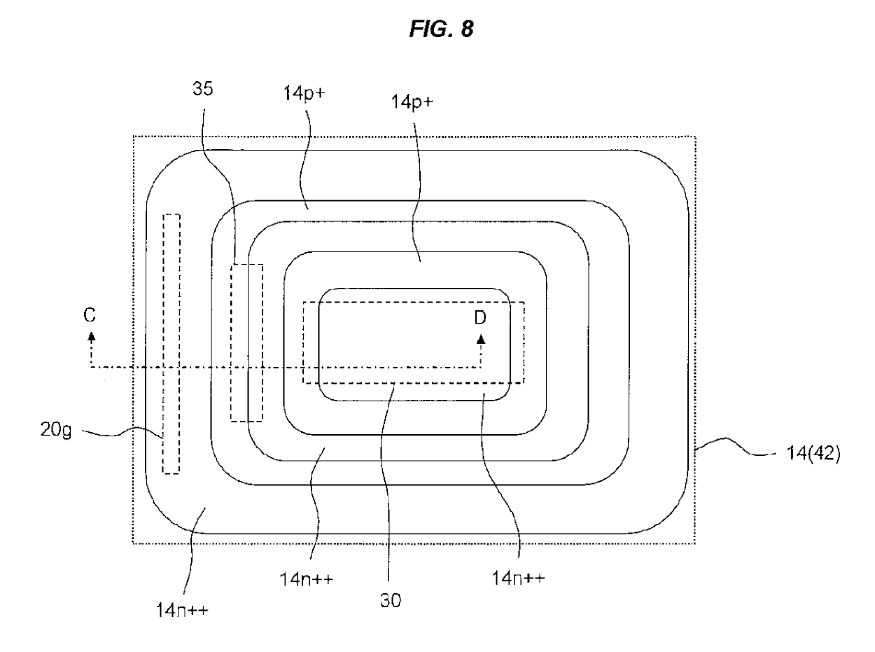

The gate protection element 14 explained in this section is a modified example of the one-dimensional type explained in the sections 1 and 2. This can be understood from that a C-D section in FIG. 7 and FIG. 8 below corresponds to that in FIG. 3 and FIG. 5, respectively, in terms of structure except for the number of stages (in actuality, the number of stages is the same as that of the one-dimensional type, however, for reasons of schematic representation, the number of stages is represented in a somewhat smaller number). By converting the one-dimensional type into a two-dimensional type as described above, it is possible to cause the corner part to have a sufficiently large R and to expect stabilization of the diode operation.

FIG. 6 is a schematic section view, substantially corresponding to the A-B section (solid line part) in FIG. 1, of a device chip including a device structure (single gate structure) of a power MOSFET and a gate protection element (two-dimensional type), which is the example of the semiconductor device in the embodiment of the present application. FIG. 7 is an enlarged top view of the gate protection element (two-dimensional multi-concentration type) in FIG. 6. FIG. 8 is an enlarged top view of a modified example (two-dimensional short circuit type) of the gate protection element in FIG. 6. Based on these, the geometrically modified example 2 (two-dimensional type) of the gate protection element in the device structure etc. of the power MOSFET, which is the example of the semiconductor device in the embodiment of the present application, is explained.

(1) Modified Example of the Gate Protection Element in FIG. 3 Converted into the Two-Dimensional Type (Mainly FIG. 6 and FIG. 7)

As shown in FIG. 6 and FIG. 7, the gate protection element 14 is, for example, the integrated bidirectional Zener diode 42 formed by the second layer polysilicon film, in which the N-type high concentration region 14n++, the P-type intermediate concentration region 14p+, and the P-type high concentration region 14p++ each having a cylindrical shape are linked repeatedly in a concentric and circulating manner from the side of the gate side contact part 20g and the center part is the N-type high concentration region 14n++, forming the source side contact part 20s. Consequently, in FIG. 1 and FIG. 2, the withstand voltage of the bidirectional Zener diode 42 when the metal gate electrode 27 (gate terminal) is negatively biased compared to the metal source electrode 26 (source terminal) is considerably lower than the withstand voltage when a backward voltage is applied. As described above, the withstand voltage characteristics of the gate protection element 14 are asymmetric with respect to the direction of the applied bias, and therefore, it is possible to effectively prevent the deterioration caused by ESD of the gate insulating film.

(2) Modified Example of the Gate Protection Element in FIG. 5 Converted into the Two-Dimensional Type (Mainly FIG. 8)

As shown in FIG. 8, the gate protection element 14 is, for example, the integrated bidirectional Zener diode 42 formed by the second layer polysilicon film, in which the N-type high concentration region 14n++ and the P-type intermediate concentration region 14p+ each having a cylindrical shape are linked repeatedly in a circulating manner from the side of the gate side contact part 20g and the center part is the N-type high concentration region 14n++, forming the source side contact part 20s. In this state, the withstand voltage characteristics of the gate protection element 14 are symmetric with respect to the direction of the applied bias, and therefore, for example, as shown in FIG. 4 and FIG. 5, the withstand voltage characteristics are caused to be asymmetric by short-circuiting the N-type high concentration region 14n++ and the P-type intermediate concentration region 14p+ adjacent to each other at the source side contact, the short circuit part 30, and the short circuit part 35 by making use of a part of the aluminum-based wiring etc. Because of this, the withstand voltage of the bidirectional Zener diode 42 when the metal gate electrode 27 (gate terminal) is negatively biased compared to the metal source electrode 26 (source terminal) is considerably lower than the withstand voltage when a backward voltage is applied. As described above, the withstand voltage characteristics of the gate protection element 14 are asymmetric with respect to the direction of the applied bias, and therefore, it is possible to effectively prevent the deterioration caused by ESD of the gate insulating film.

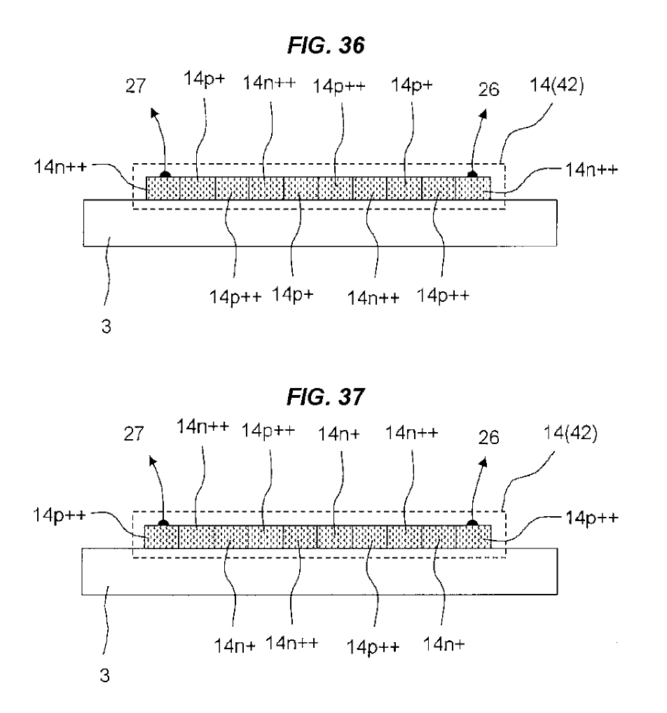

4. Explanation of a Non-Geometrically Modified Example of the Gate Protection Element in the Device Structure etc. of the Power MOSFET, which is the Example of the Semiconductor Device in the Embodiment of the Present Application (Mainly from FIG. 36 to FIG. 43)

In this section, various non-geometric variations of a schematic sectional structure including the gate protection element 14 explained in the section 1 to the section 3 are examined in a variety of ways.

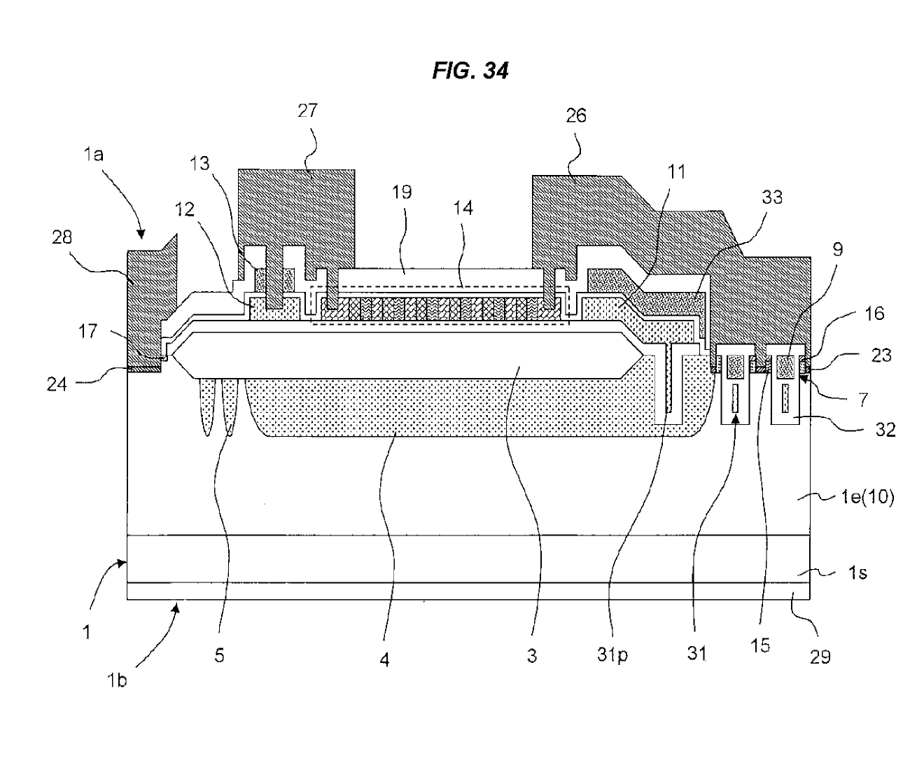

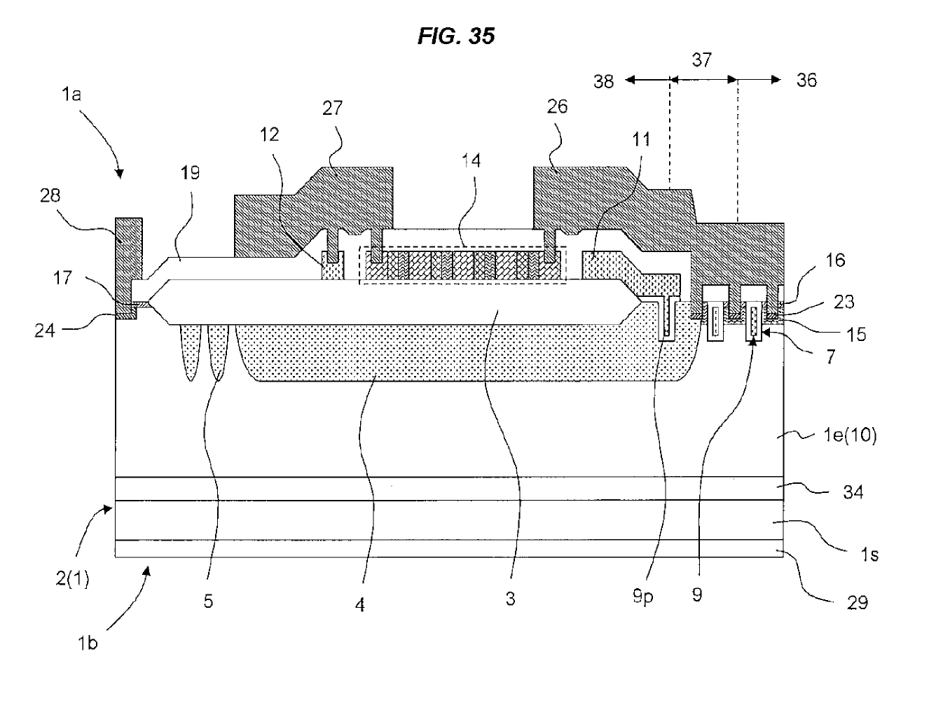

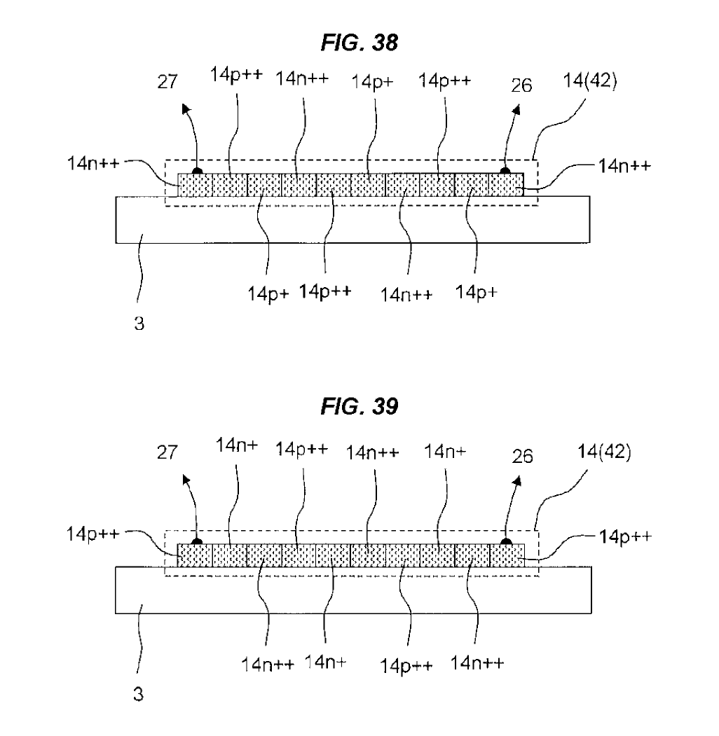

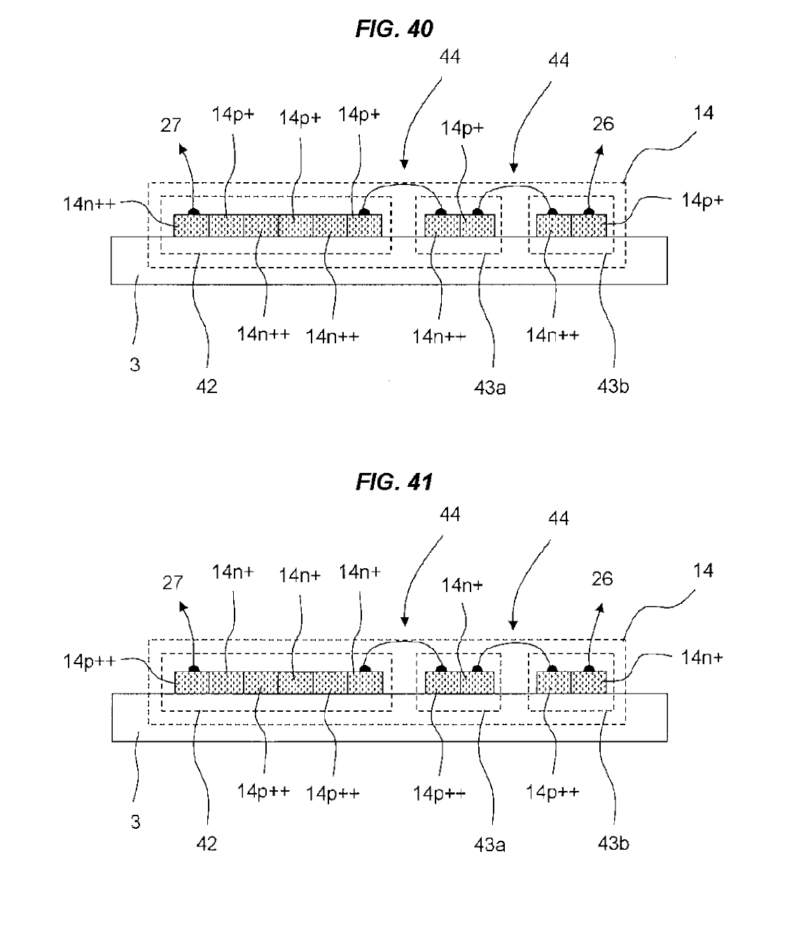

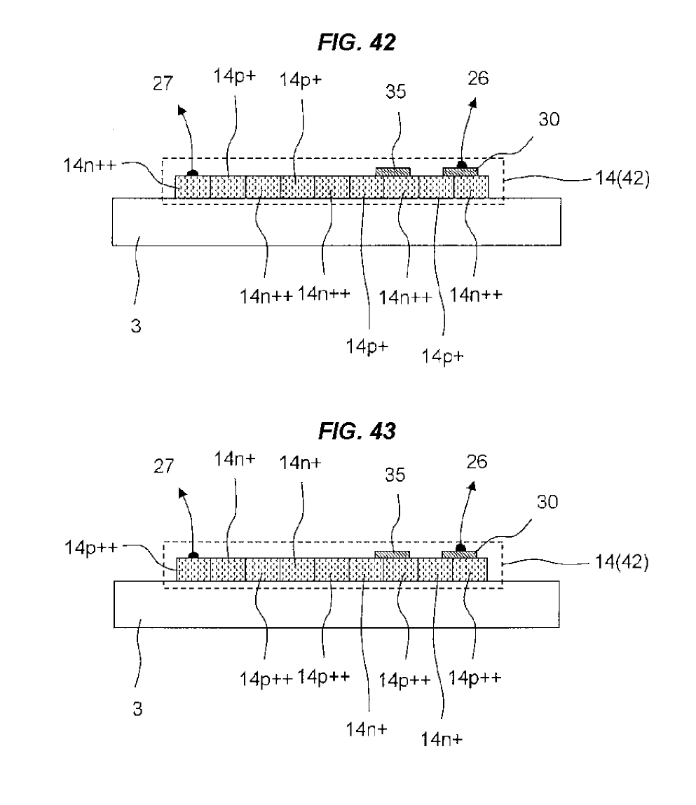

FIG. 36 is a schematic section view of a gate protection Zener diode etc. for explaining a non-geometrically modified example (N-channel transistor both end N region & multi-concentration type) of a gate protection element in a device structure etc. (for example, FIG. 2, FIG. 34, and FIG. 35) of a power MOSFET, which is one of various examples of the semiconductor device in the embodiment of the present application. FIG. 37 is a schematic section view of a gate protection Zener diode etc. for explaining a non-geometrically modified example (N-channel transistor both end P region & multi-concentration type) of a gate protection element in a device structure etc. (for example, FIG. 2, FIG. 34, and FIG. 35) of a power MOSFET, which is one of various examples of the semiconductor device in the embodiment of the present application. FIG. 38 is a schematic section view of a gate protection Zener diode etc. for explaining a non-geometrically modified example (P-channel transistor both end N region multi-concentration type) of a gate protection element in a device structure etc. (for example, FIG. 2, FIG. 34, and FIG. 35) of a power MOSFET, which is one of various examples of the semiconductor device in the embodiment of the present application. FIG. 39 is a schematic section view of a gate protection Zener diode etc. for explaining a non-geometrically modified example (P-channel transistor both end P region & multi-concentration type) of a gate protection element in a device structure etc. (for example, FIG. 2, FIG. 34, and FIG. 35) of a power MOSFET, which is one of various examples of the semiconductor device in the embodiment of the present application. FIG. 40 is a schematic section view of a gate protection Zener diode etc. for explaining a non-geometrically modified example (N-channel transistor ohmic coupling type) of a gate protection element in a device structure etc. (for example, FIG. 2, FIG. 34, and FIG. 35) of a power MOSFET, which is one of various examples of the semiconductor device in the embodiment of the present application. FIG. 41 is a schematic section view of a gate protection Zener diode etc. for explaining a non-geometrically modified example (P-channel transistor ohmic coupling type) of a gate protection element in a device structure etc. (for example, FIG. 2, FIG. 34, and FIG. 35) of a power MOSFET, which is one of various examples of the semiconductor device in the embodiment of the present application. FIG. 42 is a schematic section view of a gate protection Zener diode etc. for explaining a non-geometrically modified example (N-channel transistor both end N region & short circuit type) of a gate protection element in a device structure etc. (for example, FIG. 2, FIG. 34, and FIG. 35) of a power MOSFET, which is one of various examples of the semiconductor device in the embodiment of the present application. FIG. 43 is a schematic section view of a gate protection Zener diode etc. for explaining a non-geometrically modified example (P-channel transistor short circuit type) of a gate protection element in a device structure etc. (for example, FIG. 2, FIG. 34, and FIG. 35) of a power MOSFET, which is one of various examples of the semiconductor device in the embodiment of the present application. Based on these, various non-geometrically modified examples of the gate protection element in the device structure etc. of the power MOSFET, which is the example of the semiconductor device in the embodiment of the present application, are explained.

(1) Gate Protection Element by N-Channel Multi-Concentration Type Integrated Polysilicon Bidirectional Zener Diode (Mainly FIG. 36 and FIG. 37)

FIG. 36 is a section view schematically showing the gate protection element 14 (bidirectional Zener diode 42) both ends of which are as shown in FIG. 3.

However, this structure can constitute structures substantially equivalent thereto by performing an appropriate substitution operation. For example, one of them is the structure shown in FIG. 37. A comparison between the structure in FIG. 37 and that in FIG. 36 reveals that the structure in FIG. 37 has an advantage that the contact resistance is small because both ends are the N-type high concentration regions.

(2) Gate Protection Element by P-Channel Multi-Concentration Type Integrated Polysilicon Bidirectional Zener Diode (Mainly FIG. 38 and FIG. 39)

The gate protection element for an N-channel type transistor needs to be formed so that the withstand voltage of the bidirectional Zener diode 42 when the metal gate electrode 27 (gate terminal) is positively biased compared to the metal source electrode 26 (source terminal) is considerably lower than the withstand voltage when a backward voltage is applied. Consequently, as shown in FIG. 38, the gate protection element 14 is, for example, the integrated bidirectional Zener diode 42 formed by the second layer polysilicon film, in which the N-type high concentration region 14n++, the P-type intermediate concentration region 14p+, and the P-type high concentration region 14p++ each having a cylindrical shape are linked repeatedly in a circulating manner from the side of the source side contact part 20s and the last one is the N-type high concentration region 14n++, forming the gate side contact part 20g.

However, this structure can constitute structures substantially equivalent thereto by performing an appropriate substitution operation. For example, one of them is the structure shown in FIG. 39. A comparison between the structure in FIG. 39 and that in FIG. 38 reveals that the structure in FIG. 38 has an advantage that the contact resistance is small because both ends are the N-type high concentration regions.

(3) N & P-Channel Isolation Zener Diode Interactive Ohmic Coupling Type Gate Protection Element (Mainly FIG. 40 and FIG. 41)

As the method of constituting the gate protection element 14, besides those shown in (1), (2) in this section, it is also possible to constitute the gate protection element 14 by interactively linking one bidirectional Zener diode 42 the characteristics of which are symmetric with respect to the direction of voltage application and one or more other Zener diodes 43a, 43b (Zener diode having a single PN junction is always asymmetric with respect to the direction of voltage application) in an ohmic manner at an ohmic interactive linking unit 44 to couple them in series instead of constituting the gate protection element 14 as the single bidirectional Zener diode 42 as shown in FIG. 40 (N-channel isolation Zener diode interactive ohmic coupling type gate protection element). It is also possible to use another bidirectional Zener diode the characteristics of which are symmetric with respect to the direction of voltage application instead of the other Zener diodes 43a, 43b.

As the configuration of the P-channel isolation Zener diode interactive ohmic coupling type gate protection element 14, mention is made, for example, of the configuration shown in FIG. 41.

(4) N & P-Channel Integrated Polysilicon Bidirectional Zener Diode Partial Short Circuit Type Gate Protection Element (Mainly FIG. 42 and FIG. 43)

FIG. 42 is a section view schematically showing the gate protection element 14 (bidirectional Zener diode 42) both ends of which are as shown in FIG. 5.

However, this structure can constitute structures substantially equivalent thereto by performing an appropriate substitution operation. For example, one of them is the structure shown in FIG. 43. A comparison between the structure in FIG. 43 and that in FIG. 42 reveals that the structure in FIG. 42 has an advantage that the contact resistance is small because both ends are the N-type high concentration regions.

(5) Consideration about Two-Dimensional Type Gate Protection Element (see FIG. 6 to FIG. 8)

The gate protection elements shown in (1) to (4) in this section can be used as the one-dimensional type gate protection element as shown in FIG. 3 or FIG. 5 with almost no modification and further, as the two-dimensional type gate protection element as shown in FIG. 6 to FIG. 8.

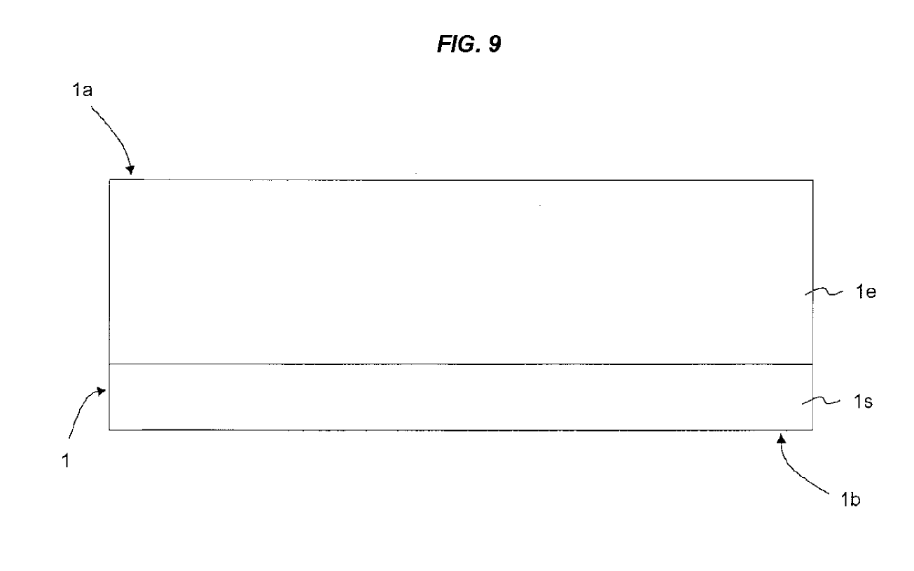

5. Explanation of a Wafer Process Corresponding to the Device Structure (Single Gate Structure) of the Power MOSFET and the Gate Protection Element (One-Dimensional Multi-Concentration Type), which is the Example of the Semiconductor Device in the Embodiment of the Present Application (Mainly from FIG. 9 to FIG. 19).

In this section, specific explanation is given with the device structure in the section 1 as an example, however, it is needless to say that the following process can be applied to the other structures and their combinations explained hitherto with almost no modification.

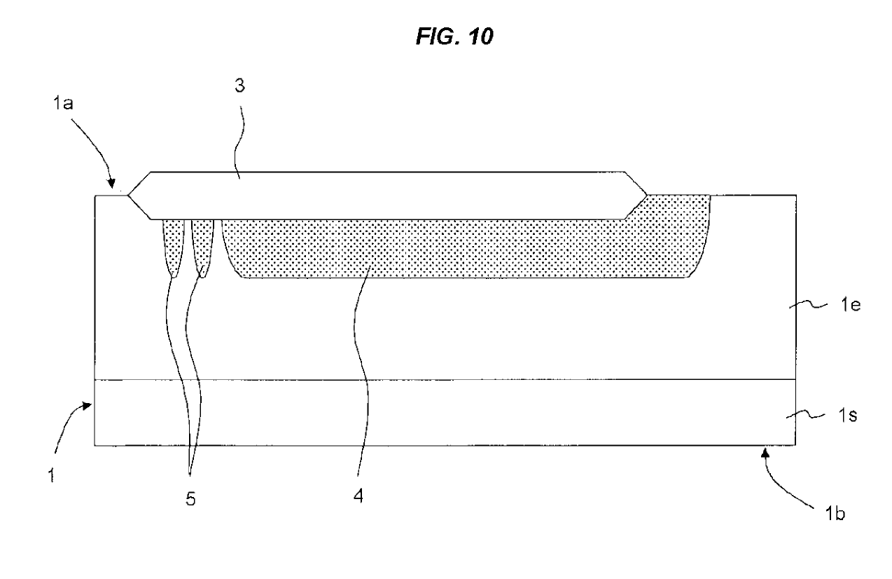

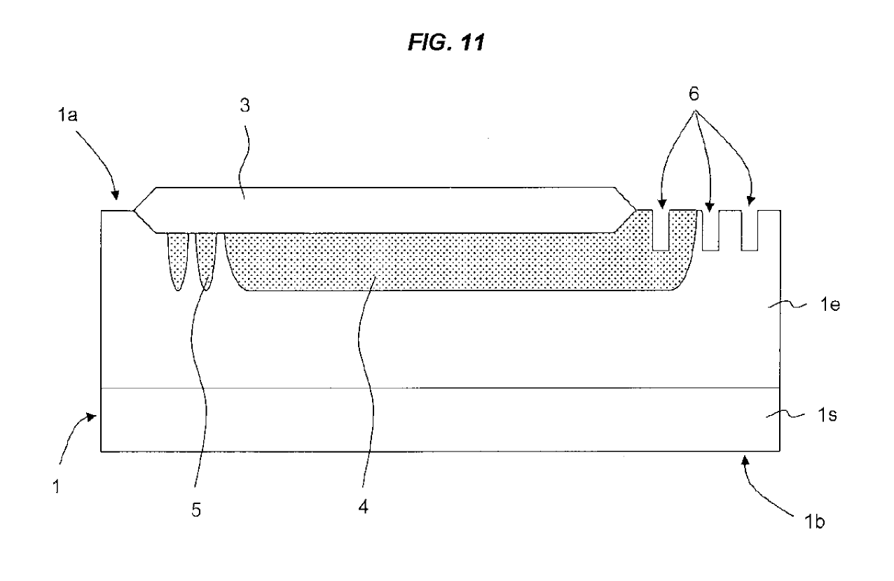

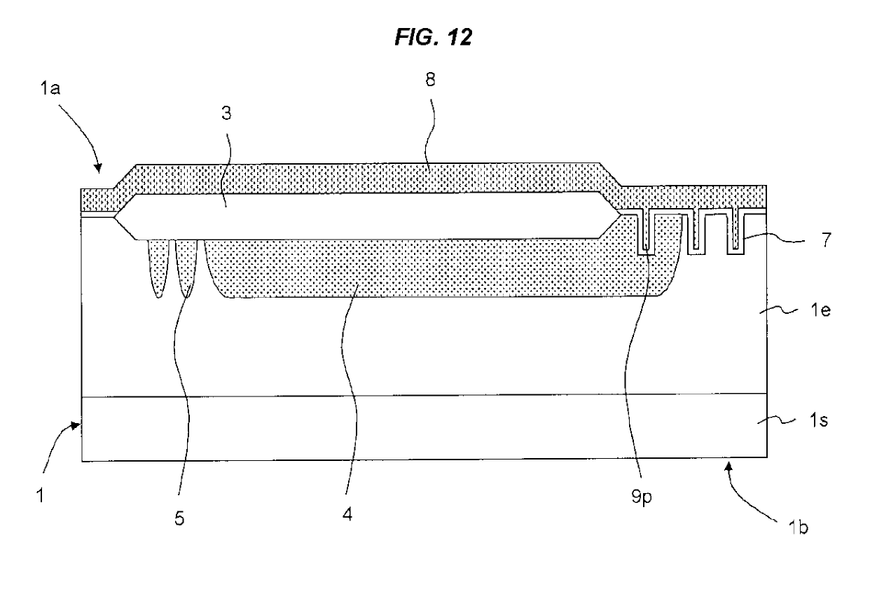

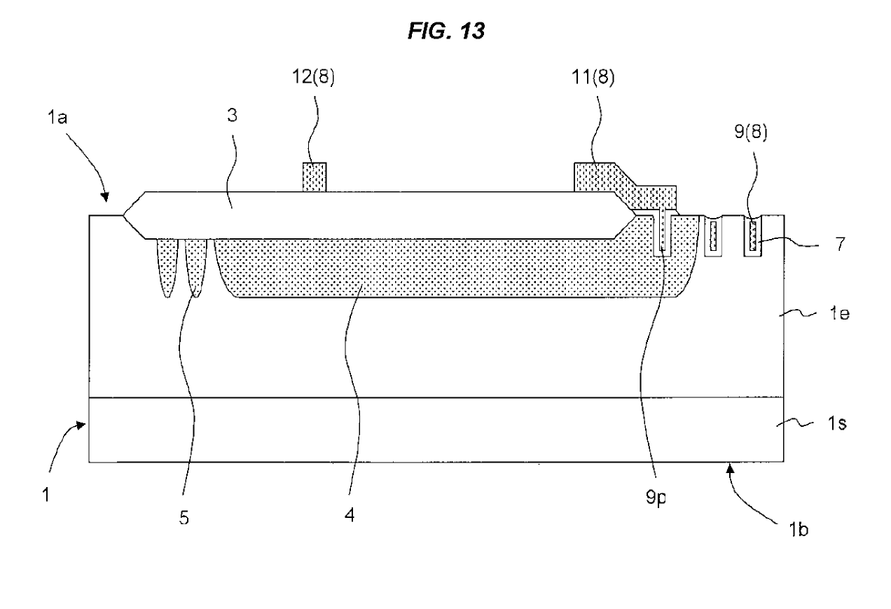

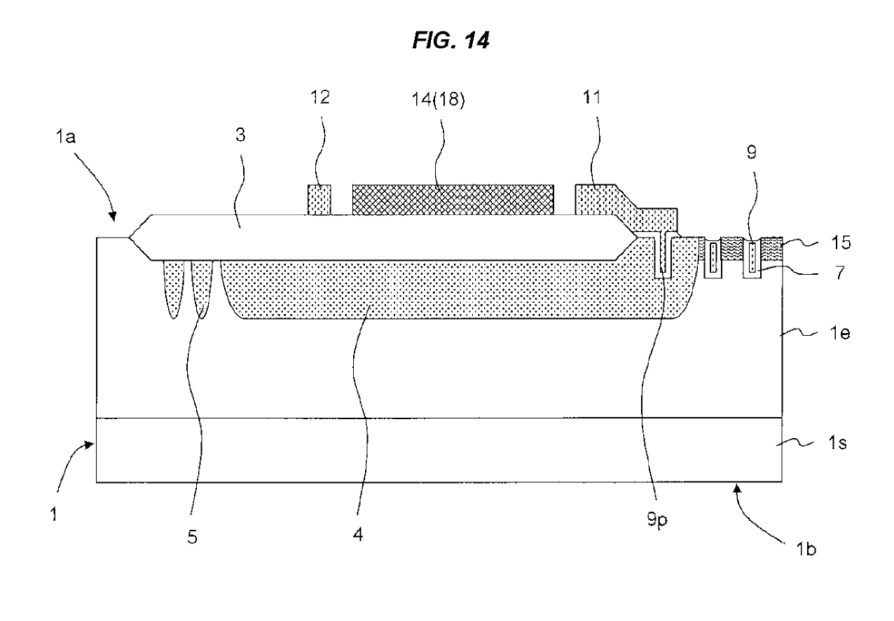

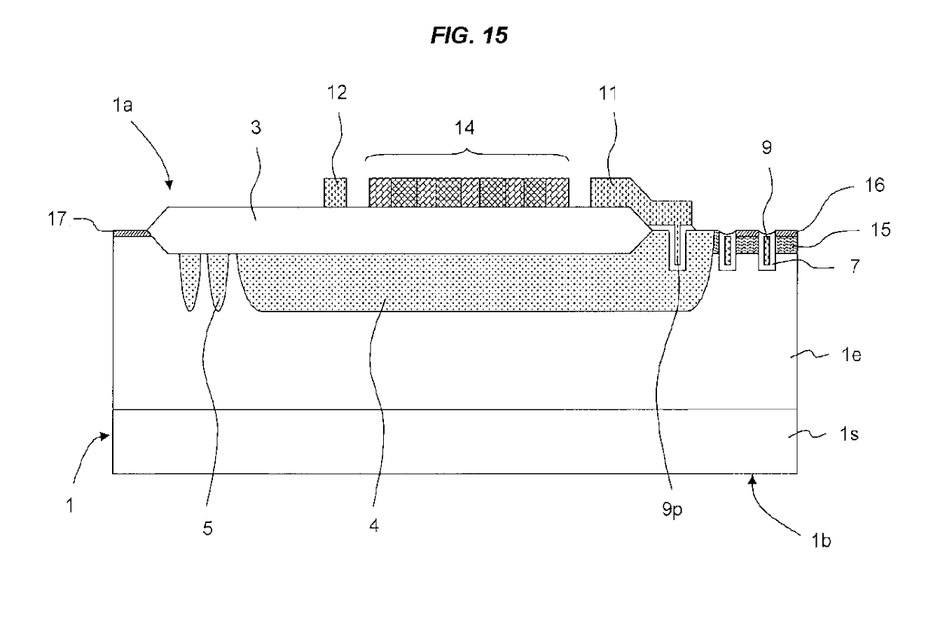

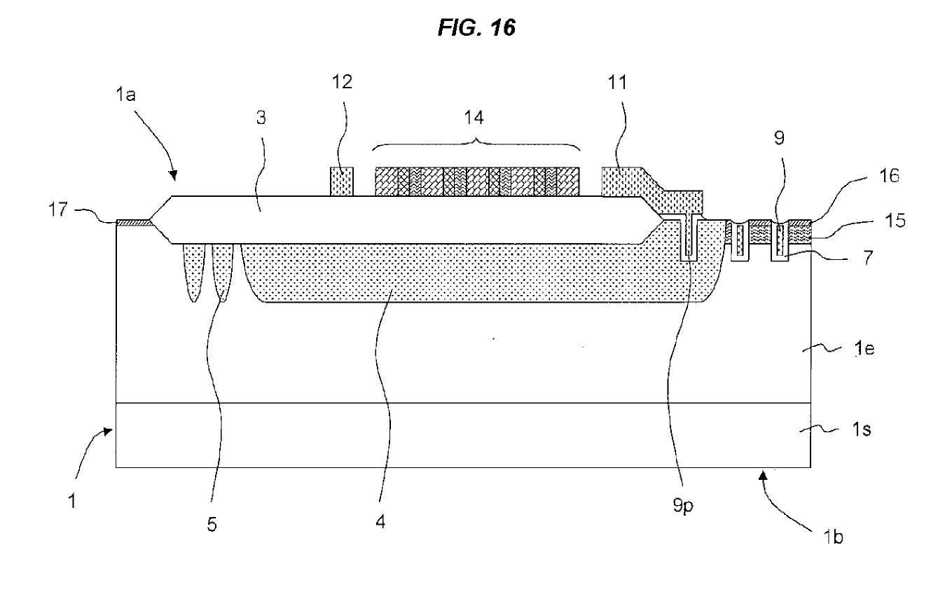

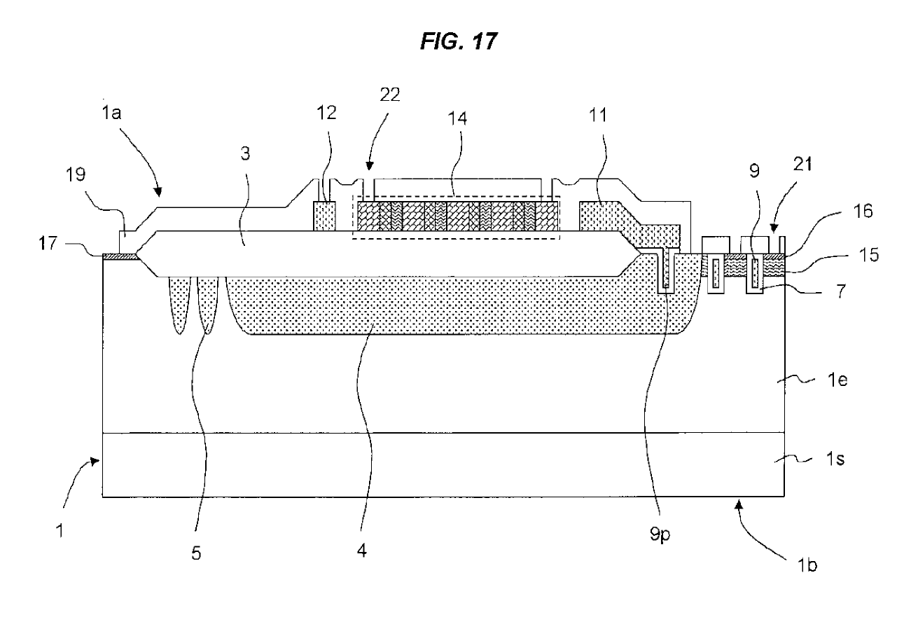

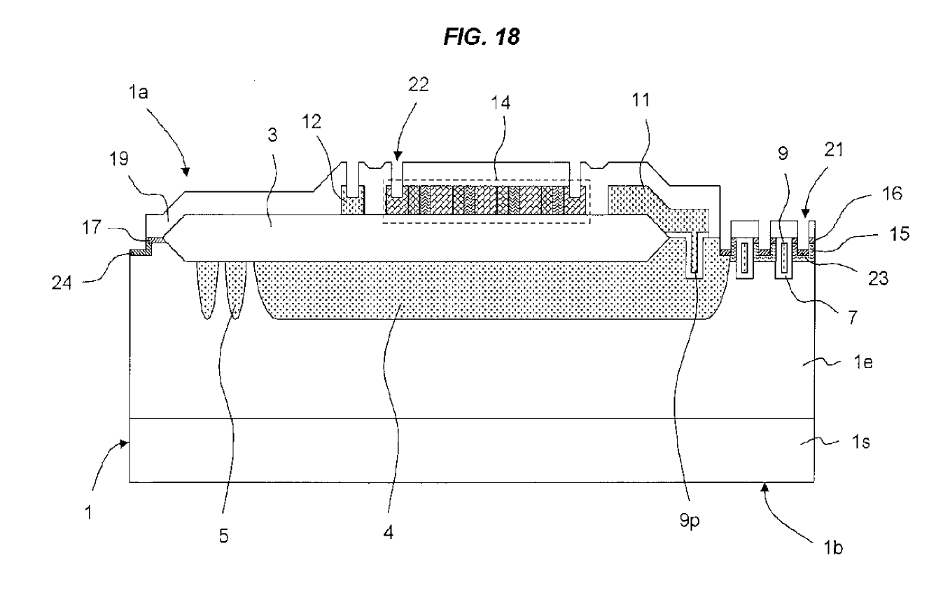

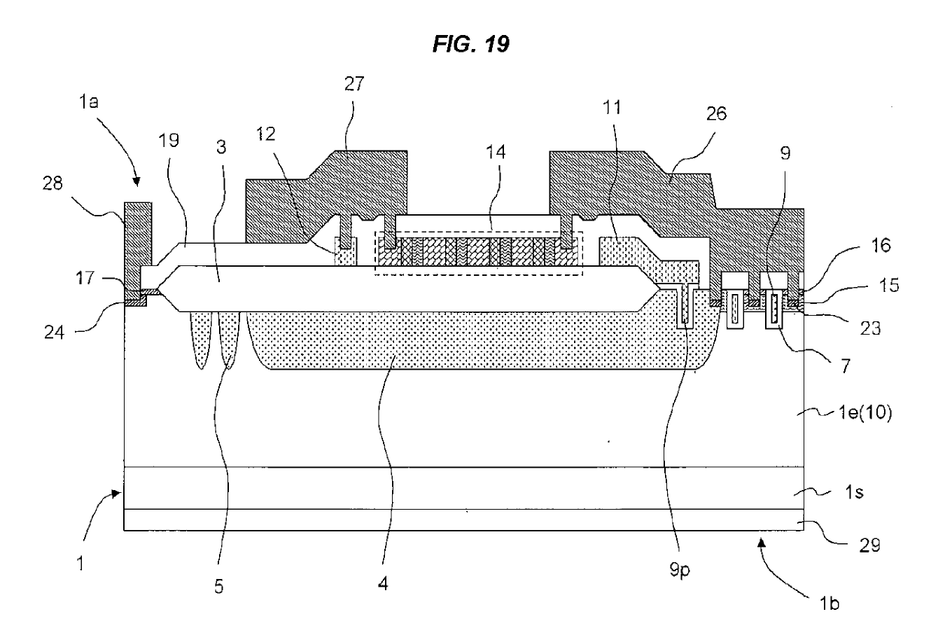

FIG. 9 is a device section view in each wafer process step (epitaxial wafer provision step) corresponding to FIG. 2 of the device chip including the power MOSFET (insulating gate power transistor) and the gate protection element (one-dimensional multi-concentration type), which is the example of the semiconductor device in the embodiment of the present application. FIG. 10 is a device section view in each wafer process step (well introduction and LOCOS silicon oxide film formation step) corresponding to FIG. 2 of the device chip including the power MOSFET (insulating gate power transistor) and the gate protection element (one-dimensional multi-concentration type), which is the example of the semiconductor device in the embodiment of the present application. FIG. 11 is a device section view in each wafer process step (trench formation step) corresponding to FIG. 2 of the device chip including the power MOSFET (insulating gate power transistor) and the gate protection element (one-dimensional multi-concentration type), which is the example of the semiconductor device in the embodiment of the present application. FIG. 12 is a device section view in each wafer process step (gate oxide film formation and doped polysilicon film deposition step) corresponding to FIG. 2 of the device chip including the power MOSFET (insulating gate power transistor) and the gate protection element (one-dimensional multi-concentration type), which is the example of the semiconductor device in the embodiment of the present application. FIG. 13 is a device section view in each wafer process step (gate processing step) corresponding to FIG. 2 of the device chip including the power MOSFET (insulating gate power transistor) and the gate protection element (one-dimensional multi-concentration type), which is the example of the semiconductor device in the embodiment of the present application. FIG. 14 is a device section view in each wafer process step (undoped polysilicon film deposition, processing, and boron ion injection step) corresponding to FIG. 2 of the device chip including the power MOSFET (insulating gate power transistor) and the gate protection element (one-dimensional multi-concentration type), which is the example of the semiconductor device in the embodiment of the present application. FIG. 15 is a device section view in each wafer process step (step of injecting arsenic ions into source, channel stop, ESD protection Zener diode, etc.) corresponding to FIG. 2 of the device chip including the power MOSFET (insulating gate power transistor) and the gate protection element (one-dimensional multi-concentration type), which is the example of the semiconductor device in the embodiment of the present application. FIG. 16 is a device section view in each wafer process step (step of additionally injecting boron ions into ESD protection Zener diode, etc.) corresponding to FIG. 2 of the device chip including the power MOSFET (insulating gate power transistor) and the gate protection element (one-dimensional multi-concentration type), which is the example of the semiconductor device in the embodiment of the present application. FIG. 17 is a device section view in each wafer process step (interlayer insulating film deposition and contact hole etc. opening step) corresponding to FIG. 2 of the device chip including the power MOSFET (insulating gate power transistor) and the gate protection element (one-dimensional multi-concentration type), which is the example of the semiconductor device in the embodiment of the present application. FIG. 18 is a device section view in each wafer process step (step of extending contact hole etc. and injecting boron etc. ions into body contact region) corresponding to FIG. 2 of the device chip including the power MOSFET (insulating gate power transistor) and the gate protection element (one-dimensional multi-concentration type), which is the example of the semiconductor device in the embodiment of the present application. FIG. 19 is a device section view in each wafer process step (surface metal deposition, processing, back grinding, and back surface metal deposition step) corresponding to FIG. 2 of the device chip including the power MOSFET (insulating gate power transistor) and a gate protection element (one-dimensional multi-concentration type), which is the example of the semiconductor device in the embodiment of the present application. Based on these, the wafer process corresponding to the device structure (single gate structure) of the power MOSFET and the gate protection element (one-dimensional multi-concentration type), which is the example of the semiconductor device in the embodiment of the present application, is explained.

First, as shown in FIG. 9, on the single crystal N-type silicon substrate is (for example, CZ crystal) having comparatively low specific resistance, the epitaxy wafer 1 is provided, which has a thickness according to a source drain withstand voltage (BVdss) of a power MOSFET to be manufactured and in which the N-type epitaxy layer 1e having a comparatively high specific resistance is grown. The specific resistance of the single crystal N-type silicon substrate is, for example, about 1 to 10 mΩcm and the diameter of the wafer 1 is, for example, about 200φ. The diameter of the wafer 1 may be any of 100φ, 150φ, 300φ, 450φ, etc., other than 200φ. The thickness and the specific resistance of the N-type epitaxy layer 1e depend on the source drain withstand voltage and as the thickness of the source drain withstand voltage of about 40 V, mention is made, for example, of about 4 to 6 μm and as the specific resistance, mention is made, for example, of about 0.4 to 0.8 Ω·cm. Normally, a rough estimate of the thickness (μm) of the epitaxy layer is about one-tenth of the figure of the withstand voltage value (V).

Next, as shown in FIG. 10, the P well region 4 and the P-type field limiting ring 5 are formed by injecting, for example, born ions into the surface 1a of the wafer 1 using, for example, a resist film as a mask. At this time, as a dose, mention is made, for example, of about 5×10¹² to 1×10¹⁴ cm⁻² and as injection energy, mention is made, for example, of about 10 to 100 keV. Subsequently, the field insulating film 3 (having a thickness of, for example, about 200 nm) is formed by, for example, the LOCOS (Local Oxidation of Silicon) method.

Next, as shown in FIG. 11, the trench 6 is formed by anisotropic dry etching etc. using, for example, a trench processing mask (for example, hard mask) etc. patterned by the normal lithography. As the gas for dry etching, mention is made, for example, of the Cl₂-based gas, the O₂-based gas, the HBr-based gas, etc.

Next, as shown in FIG. 12, the gate oxide film 7 (having a thickness of, for example, about 50 nm) is formed over substantially the entire surface of the surface 1a of the wafer 1 by, for example, thermal oxidation. Subsequently, the high concentration phosphorus-doped polysilicon film 8 (first layer polysilicon film) having a thickness of, for example, about 600 nm is formed over substantially the entire surface of the surface 1a of the wafer 1 by CVD (Chemical Vapor Deposition) etc.

Next, as shown in FIG. 13, the first layer polysilicon wiring 12, the first layer polysilicon extraction unit 11, the polysilicon gate electrode 9, the peripheral dummy polysilicon gate electrode 9p, etc., are formed by performing etch back processing as well as patterning the high concentration phosphorus-doped polysilicon film 8 by dry etching (as the etching gas, mention is made, for example, of SF6 etc.) etc. using a gate processing mask (for example, resist film) etc. patterned by the normal lithography.

Next, after forming a thin silicon oxide film (having a thickness of, for example, about 10 nm) (this film is thin and therefore not shown schematically) over substantially the entire surface of the surface 1a of the wafer 1 by, for example, CVD etc., as shown in FIG. 14, the undoped polysilicon film 18 (second layer polysilicon film) is formed on substantially the entire surface of the surface 1a of the wafer 1 by, for example, CVD etc., and then, P-type impurities are doped by ion injection using, for example, a patterned resist film as a mask at the part to form the gate protection element 14. As the conditions on the ion injection at this time, mention is made, for example, of the ion kind of, for example, BF₂, the dose of, for example, about 1×10¹³ to 1×10¹⁴ cm⁻², and the injection energy of, for example, about 10 to 100 keV. Subsequently, the second layer polysilicon film 18 is patterned by dry etching (as the etching gas, mention is made, for example, of SF6 etc.) etc. using a polysilicon film processing mask (for example, resist film) etc. patterned by the normal lithography. Further, ions are injected using a resist film etc. as a mask into the part to form the P body region 15 (channel region) of the surface 1a of the wafer 1. As the conditions on the ion injection at this time, mention is made, for example, of the ion kind of, for example, boron, the dose of, for example, about 1×10¹² to 5×10¹³ m⁻², and the injection energy of, for example, about 50 to 200 keV.

Next, as shown in FIG. 15, the N-type source region 16, the N-type channel stop region 17, the N-type high concentration region 14n++ (for example, FIGS. 36, 38, 40, and 42) of the ESD (Electro-Static Discharge) protection polysilicon Zener diode of the gate protection element 14, etc., are formed by injecting ions using a resist film etc. as a mask. As the conditions on the ion injection at this time, mention is made, for example, of the ion kind of, for example, arsenic, the dose of, for example, about 1×10¹⁵ to 1×10¹⁶ cm⁻², and the injection energy of, for example, about 10 to 150 keV.

Next, as shown in FIG. 16, by performing additional ion injection using a resist film etc. as a mask, the part into which ions are injected additionally forms the P-type high concentration region 14p++ (for example, FIG. 36 and FIG. 43) of the ESD protection polysilicon Zener diode of the gate protection element 14 and the part of the P-type part into which ions are not injected additionally forms the P-type intermediate concentration region 14p+ (for example, FIG. 36 and FIG. 43). As the conditions on the ion injection at this time, mention is made, for example, of the ion kind of, for example, boron, the dose of, for example, about 1.5×10¹⁵ to 2×10¹⁶ cm⁻², and the injection energy of, for example, about 10 to 150 keV.

Next, as shown in FIG. 17, over substantially the entire surface of the surface 1a of the wafer 1, the interlayer insulating film 19 (having a thickness of, for example, about 250 to 450 nm), such as a PSG (Phospho Silicate Glass) film, is formed by, for example, CVD etc. Preferably, the interlayer insulating film 19 includes a silicon oxide-based insulating film as a principal element and in addition to the PSG film, a single film such as a BPSG (Boro-Phosopho Silicate Glass) film, a compound film of the BPSG film and an SOG (Spin-On-Glass) film or TEOS (Tetraethylorthosilicate) film, etc., are also preferable. Next, a contact hole 21, a coupling via 22, etc., are formed by forming a pattern, such as a resist film, over the surface 1a of the wafer 1 and performing anisotropic dry etching using the pattern as a mask. After that, the resist film etc. that are no longer necessary are removed.

Next, as shown in FIG. 18, the contact hole 21, the coupling via 22, etc., are extended downward (for example, about 0.35 μm) by performing anisotropic dry etching (silicon etching) using the interlayer insulating film 19 as a mask. Subsequently, the P-type body contact region 23 and the P-type peripheral contact region 24 are introduced by performing ion injection through the contact hole 21 in the state where unnecessary parts are coated with a resist film etc. As the conditions on the ion injection at this time, mention is made, for example, of the ion kind of, for example, boron (or BF₂), the dose of, for example, about 1×10¹⁵ to 5×10¹⁶ cm⁻², and the injection energy of, for example, about 20 to 200 keV.

Next, on the inner surface of the contact hole 21 (contact groove) and substantially the entire surface of the device surface 1a of the wafer 1, for example, a barrier metal film including a Ti film (having a thickness of, for example, about 40 nm) in the lower layer, a TiN film (having a thickness of, for example, about 100 nm) in the upper layer, etc., is formed by, for example, sputtering deposition. As the barrier metal film, mention is made of TiW or others as preferable ones in addition to Ti/TiN-based films shown here.

Next, as shown in FIG. 19, on the inner surface of the contact hole 21 and substantially the entire surface of the device surface 1a of the wafer 1, for example, an aluminum-based source metal film (having a thickness of, for example, about 3.5 to 5.5 μm) including aluminum as a principal component (for example, several percent of added silicon and the rest is aluminum) is formed by, for example, sputtering deposition. Subsequently, the metal source electrode or the source pad 26 (or source terminal), the metal gate electrode 27 (gate pad or gate terminal), the metal guard ring 28, etc., are formed by patterning a source metal electrode including an aluminum-based source metal film and a barrier metal film by the normal lithography.

After that, according to the necessity, an organic film (having a thickness of, for example, about 2.5 μm) etc. including polyimide as a principal component is applied to substantially the entire surface of the device surface 1a of the wafer 1 as a final passivation film. Next, by the normal lithography, the final passivation film at the part corresponding to the source pad opening, the gate pad opening, is removed.

Next, by subjecting the back surface 1b of the wafer 1 to back grinding processing, the wafer having a thickness of about 500 to 900 μm is thinned to the wafer having a thickness of about 300 to 30 μm. After that, the back surface electrode 29 is formed by, for example, sputtering deposition. Further, by dicing etc., the wafer 1 is divided into individual chips 2.

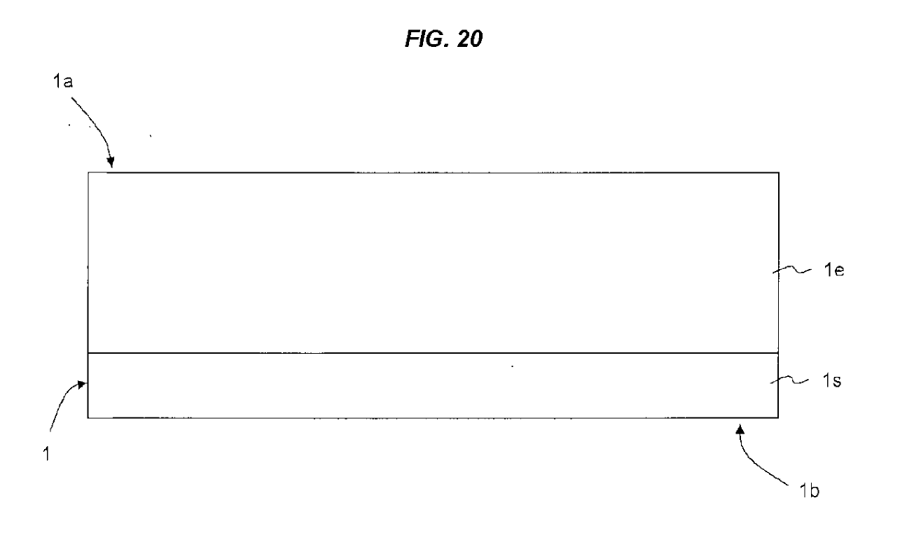

6. Explanation of a Wafer Process Corresponding to a Modified Example of the Device Structure (Double Gate Structure) of the Power MOSFET and the Gate Protection Element (One-Dimensional Multi-Concentration Type), which are the Example of the Semiconductor Device in the Embodiment of the Present Application (Mainly from FIG. 20 to FIG. 34).

The device structure in this section is the same as that in the example in the section 1 except in that the structure is the double gate structure and it is needless to say that the other examples shown in the present application can also be applied to the ESD protection element with almost no modification.

The double gate structure has an advantage that the specific resistance of the epitaxial layer can be somewhat reduced by the Resurf effect compared to the single gate structure (for example, the ON resistance can be reduced).

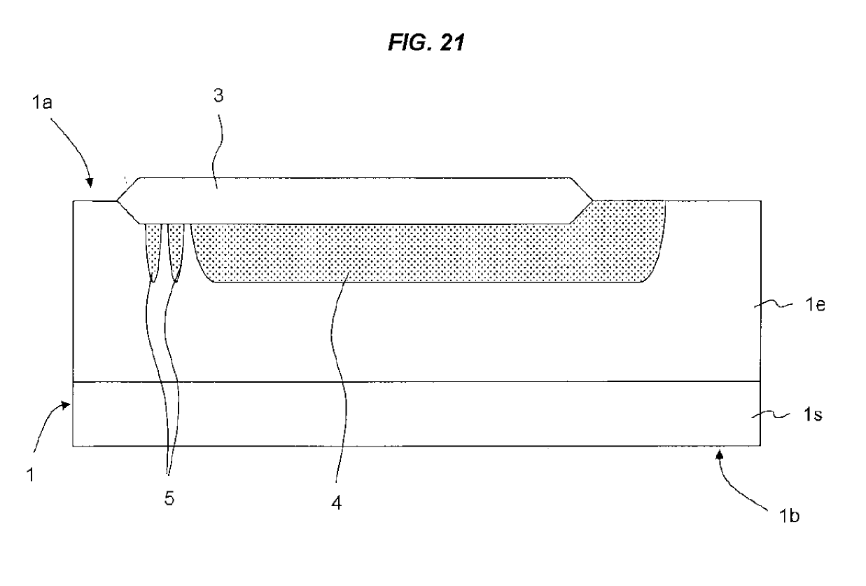

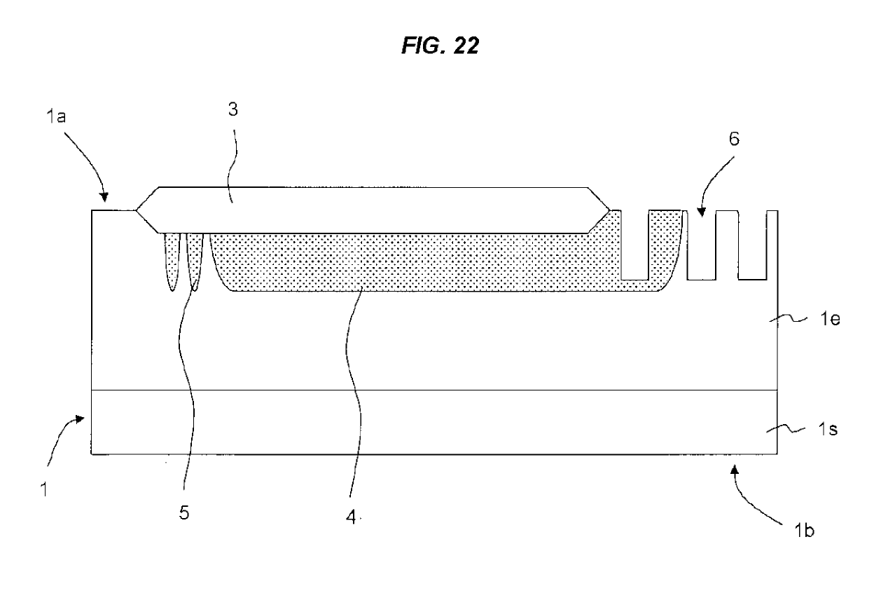

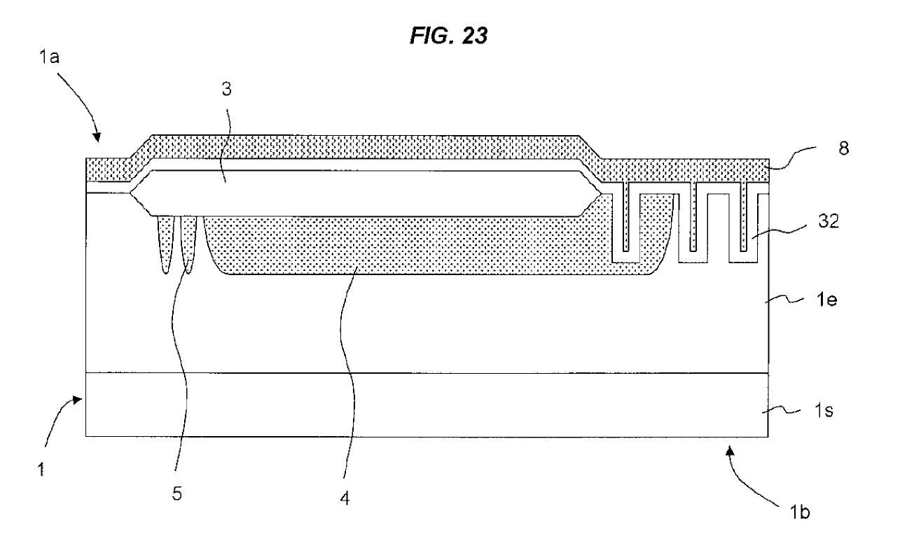

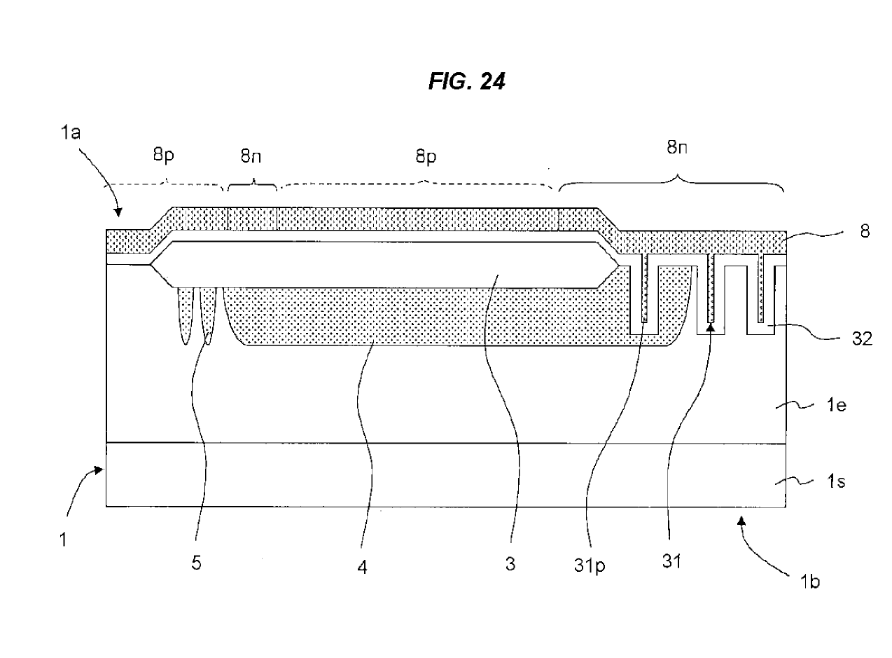

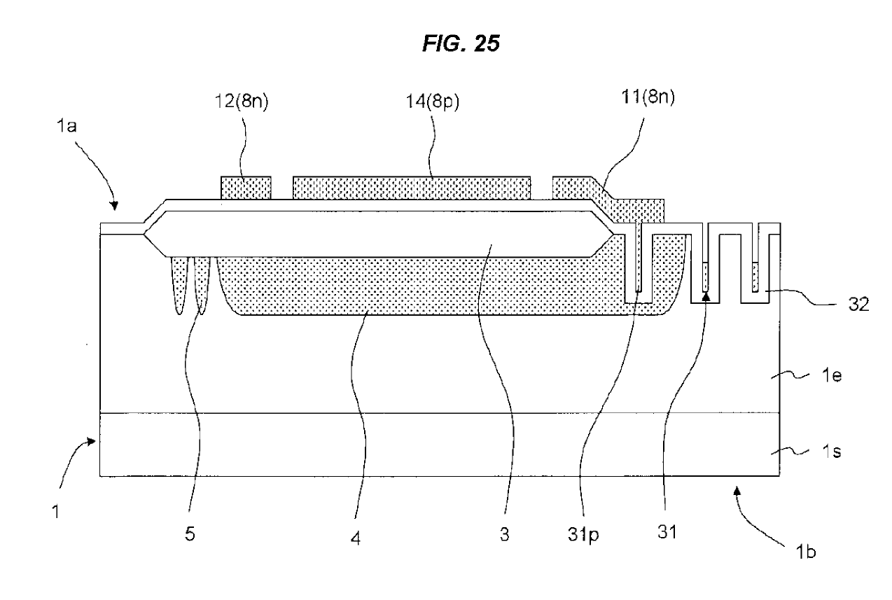

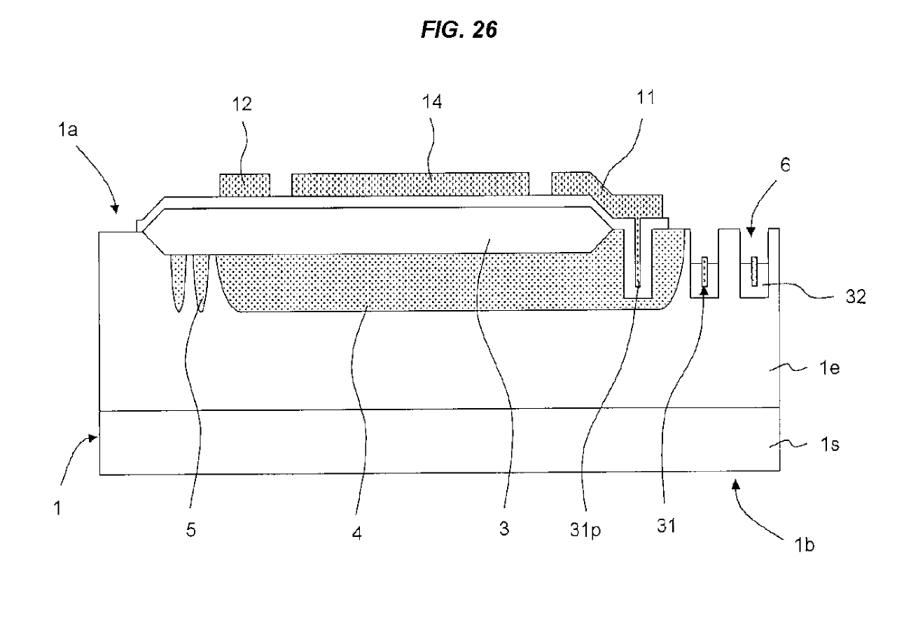

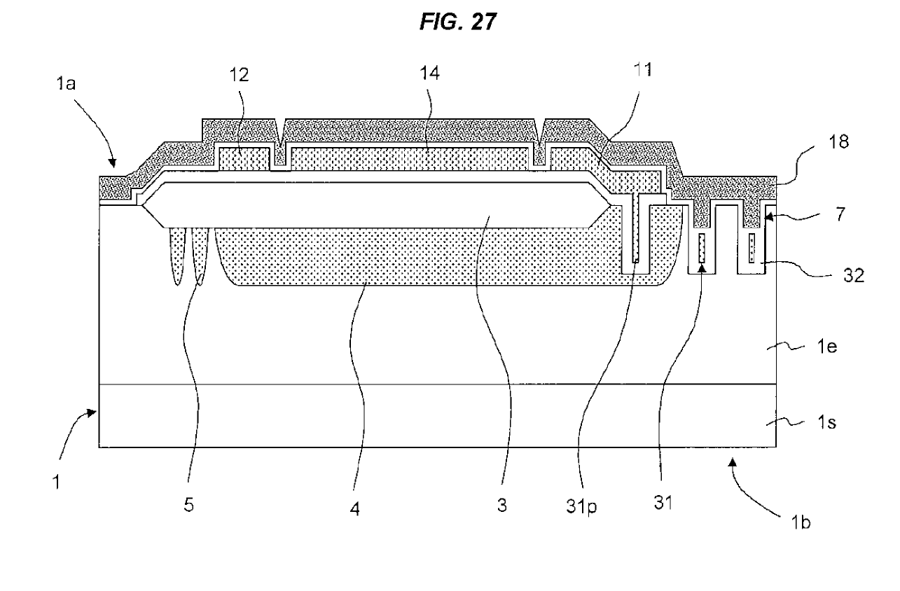

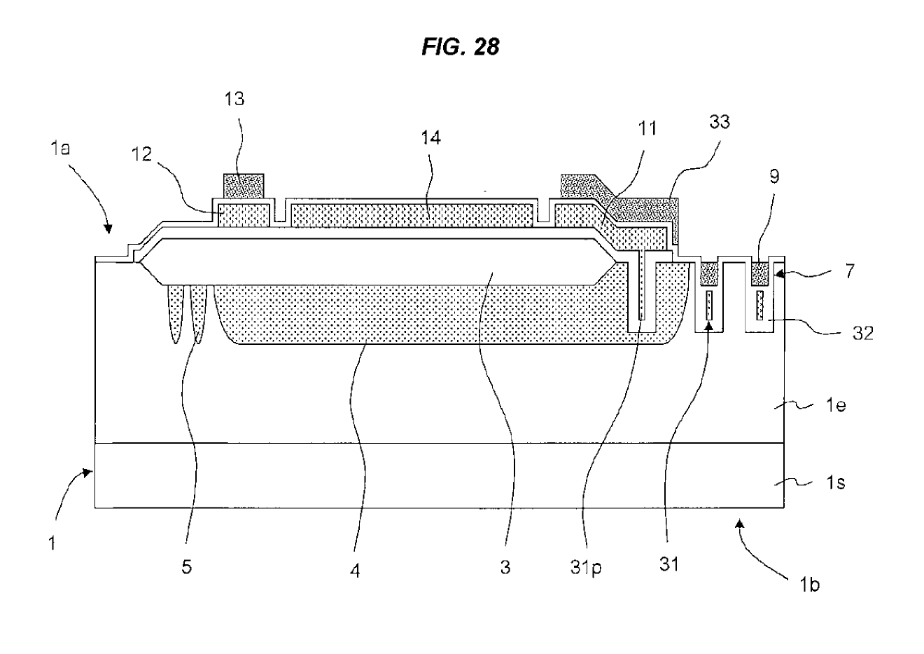

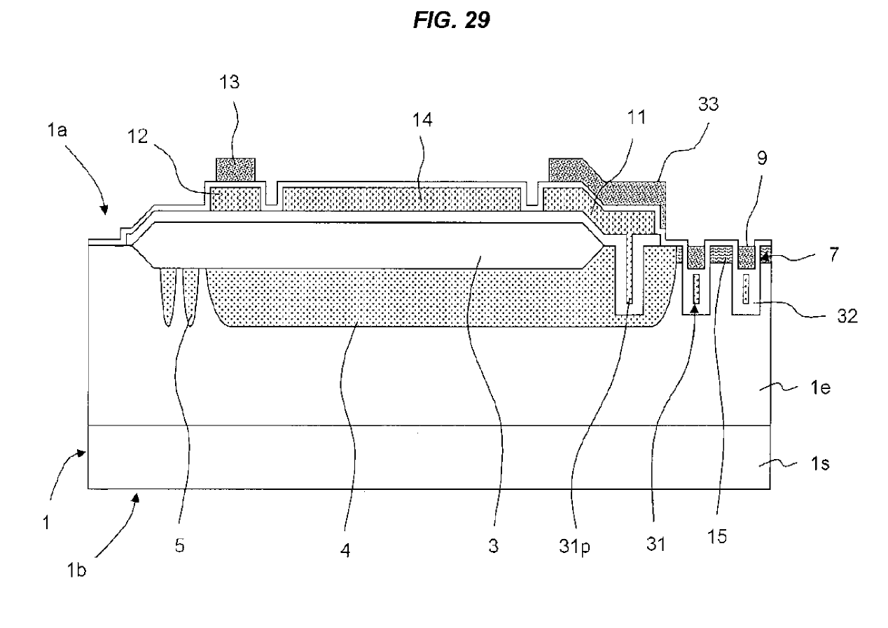

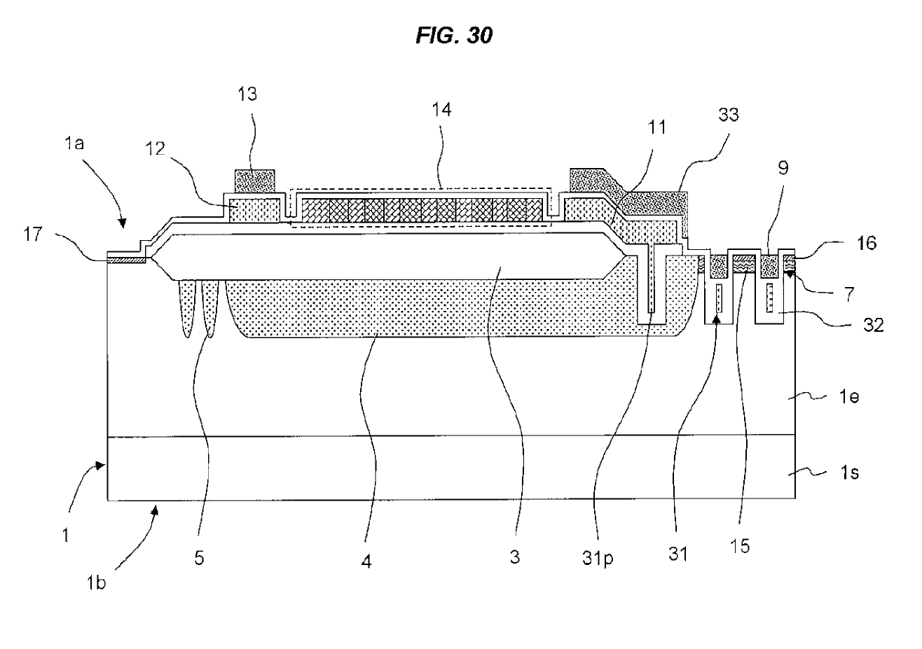

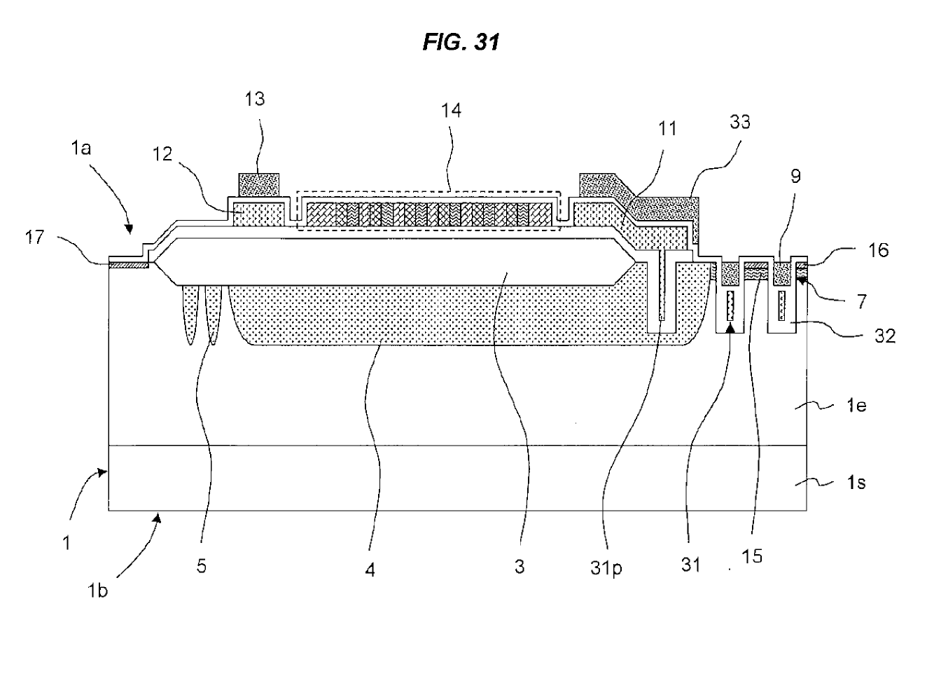

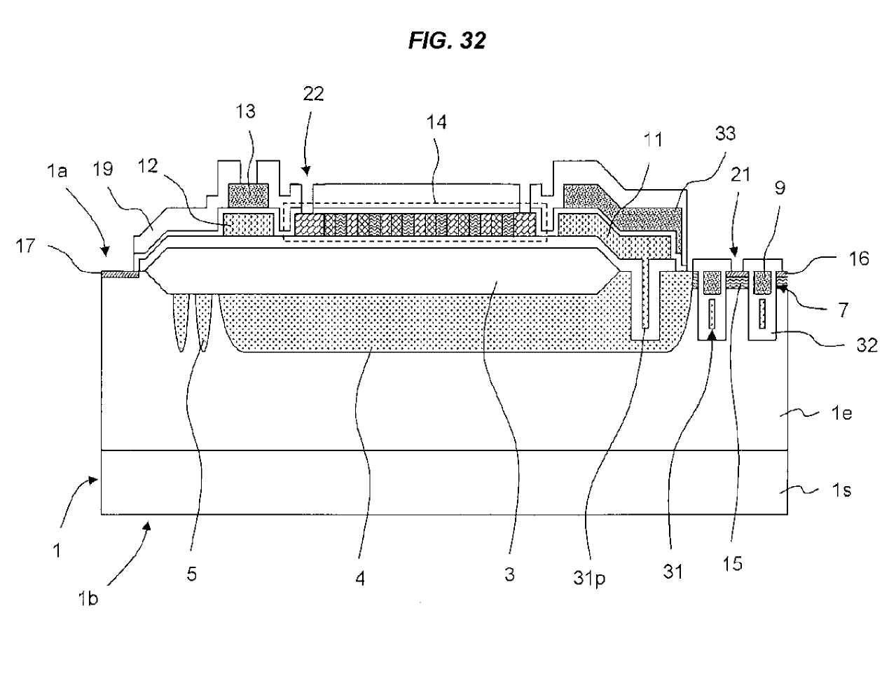

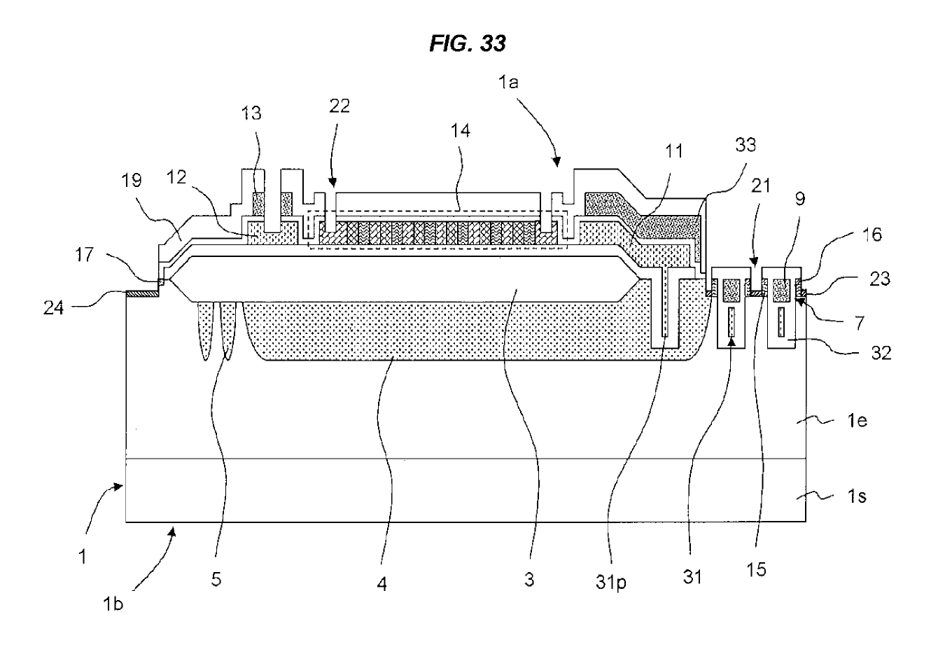

FIG. 20 is a device section view in each wafer process step (epitaxial wafer provision step) of the device chip including a modified example (double gate structure) of the device structure of the power MOSFET (insulating gate power transistor) and the gate protection element (one-dimensional multi-concentration type), which is the example of the semiconductor device in the embodiment of the present application. FIG. 21 is a device section view in each wafer process step (well introduction and LOCOS insulating film formation step) of the device chip including the modified example (double gate structure) of the device structure of the power MOSFET (insulating gate power transistor) and the gate protection element (one-dimensional multi-concentration type), which is the example of the semiconductor device in the embodiment of the present application. FIG. 22 is a device section view in each wafer process step (trench formation step) of the device chip including the modified example (double gate structure) of the device structure of the power MOSFET (insulating gate power transistor) and the gate protection element (one-dimensional multi-concentration type), which is the example of the semiconductor device in the embodiment of the present application. FIG. 23 is a device section view in each wafer process step (Resurf gate insulating film formation and undoped polysilicon film deposition step) of the device chip including the modified example (double gate structure) of the device structure of the power MOSFET (insulating gate power transistor) and the gate protection element (one-dimensional multi-concentration type), which is the example of the semiconductor device in the embodiment of the present application. FIG. 24 is a device section view in each wafer process step (step of injecting P-type impurity ions into entire surface and selectively injecting N-type impurity ions) of the device chip including the modified example (double gate structure) of the device structure of the power MOSFET (insulating gate power transistor) and the gate protection element (one-dimensional multi-concentration type), which is the example of the semiconductor device in the embodiment of the present application. FIG. 25 is a device section view in each wafer process step (first layer polysilicon film processing step) of the device chip including the modified example (double gate structure) of the device structure of the power MOSFET (insulating gate power transistor) and the gate protection element (one-dimensional multi-concentration type), which is the example of the semiconductor device in the embodiment of the present application. FIG. 26 is a device section view in each wafer process step (Resurf gate insulating film etch back step) of the device chip including the modified example (double gate structure) of the device structure of the power MOSFET (insulating gate power transistor) and the gate protection element (one-dimensional multi-concentration type), which is the example of the semiconductor device in the embodiment of the present application. FIG. 27 is a device section view in each wafer process step (intrinsic gate insulating film formation and intrinsic gate doped polysilicon film deposition step) of the device chip including the modified example (double gate structure) of the device structure of the power MOSFET (insulating gate power transistor) and the gate protection element (one-dimensional multi-concentration type), which is the example of the semiconductor device in the embodiment of the present application. FIG. 28 is a device section view in each wafer process step (intrinsic gate doped polysilicon film deposition and processing step) of the device chip including the modified example (double gate structure) of the device structure of the power MOSFET (insulating gate power transistor) and the gate protection element (one-dimensional multi-concentration type), which is the example of the semiconductor device in the embodiment of the present application. FIG. 29 is a device section view in each wafer process step (step of injecting boron ions into P body region, that is, channel region) of the device chip including the modified example (double gate structure) of the device structure of the power MOSFET (insulating gate power transistor) and the gate protection element (one-dimensional multi-concentration type), which is the example of the semiconductor device in the embodiment of the present application. FIG. 30 is a device section view in each wafer process step (step of injecting arsenic ions into source, channel stop, ESD protection Zener diode, etc.) of the device chip including the modified example (double gate structure) of the device structure of the power MOSFET (insulating gate power transistor) and the gate protection element (one-dimensional multi-concentration type), which is the example of the semiconductor device in the embodiment of the present application. FIG. 31 is a device section view in each wafer process step (step of additionally injecting boron ions into ESD protection Zener diode etc.) of the device chip including the modified example (double gate structure) of the device structure of the power MOSFET (insulating gate power transistor) and the gate protection element (one-dimensional multi-concentration type), which is the example of the semiconductor device in the embodiment of the present application. FIG. 32 is a device section view in each wafer process step (interlayer insulating film deposition and contact hole etc. opening step) of the device chip including the modified example (double gate structure) of the device structure of the power MOSFET (insulating gate power transistor) and the gate protection element (one-dimensional multi-concentration type), which is the example of the semiconductor device in the embodiment of the present application. FIG. 33 is a device section view in each wafer process step (step of extending contact hole etc. and injecting boron etc. ions into body contact region) of the device chip including the modified example (double gate structure) of the device structure of the power MOSFET (insulating gate power transistor) and the gate protection element (one-dimensional multi-concentration type), which is the example of the semiconductor device in the embodiment of the present application. FIG. 34 is a device section view in each wafer process step (surface metal deposition, processing, back grinding, and back surface metal deposition step) of the device chip including the modified example (double gate structure) of the device structure of the power MOSFET (insulating gate power transistor) and the gate protection element (one-dimensional multi-concentration type), which is the example of the semiconductor device in the embodiment of the present application. Based on these, the wafer process corresponding to the modified example of the device structure (double gate structure) of the power MOSFET and the gate protection element (one-dimensional multi-concentration type, which is the example of the semiconductor device in the first embodiment of the present application, is explained.

First, as shown in FIG. 20, on the single crystal N-type silicon substrate is (for example, CZ crystal) having a comparatively low specific resistance, the epitaxy wafer 1 is provided, which has a thickness according to the source drain withstand voltage (BVdss) of a power MOSFET to be manufactured and in which the N-type epitaxy layer 1e having a comparatively high specific resistance is grown. The specific resistance of the single crystal N-type silicon substrate is, for example, about 1 to 10 mΩcm and the diameter of the wafer 1 is, for example, about 200φ. The diameter of the wafer 1 may be any of 100φ, 150φ, 300φ, 450φ, etc., other than 200φ. The thickness and the specific resistance of the N-type epitaxy layer 1e depend on the source drain withstand voltage and as the thickness of the source drain withstand voltage of about 40 V. mention is made, for example, of about 4 to 6 μm and as the specific resistance, mention is made, for example, of about 0.3 to 0.6 Ω·cm (somewhat lower compared to that of the single gate in the section 5). Normally, a rough estimate of the thickness (μm) of the epitaxy layer is about one-tenth of the figure of the withstand voltage value (V).

Next, as shown in FIG. 21, the P well region 4 and the P-type field limiting ring 5 are formed by injecting, for example, born ions into the surface 1a of the wafer 1 using, for example, a resist film as a mask. At this time, as a dose, mention is made, for example, of about 5×10¹² to 1×10¹⁴ cm⁻² and as injection energy, mention is made, for example, of about 10 to 100 keV. Subsequently, the field insulating film 3 (having a thickness of, for example, about 200 nm) is formed by, for example, the LOCOS method.

Next, as shown in FIG. 22, the trench 6 is formed by anisotropic dry etching etc. using, for example, a trench processing mask (for example, hard mask) etc. patterned by the normal lithography. As the gas for dry etching, mention is made, for example, of the Cl₂-based gas, the O₂-based gas, the HBr-based gas, etc.

Next, as shown in FIG. 23, a Resurf gate insulating film 32 (field plate peripheral insulating film) thicker than the gate oxide film 7 (having a thickness of, for example, about 50 nm) is formed over substantially the entire surface 1a of the wafer 1 by, for example, thermal oxidation. Subsequently, the undoped polysilicon film 8 (first layer polysilicon film) having a thickness of, for example, about 600 nm is formed over substantially the entire surface of the surface 1a of the wafer 1 by CVD (Chemical Vapor Deposition) etc.

Next, as shown in FIG. 24, doping by ion injection is performed over the, entire surface of the first layer polysilicon film 8. As the conditions on the ion injection at this time, mention is made, for example, of the ion kind of, for example, BF₂, the dose of, for example, about 1×10¹³ to 1×10¹⁴ cm⁻², and the injection energy of, for example, about 10 to 100 keV. Subsequently, doping by ion injection is performed in the state where the part other than a part 8n (part to form an N-type part of the first layer polysilicon film) to be doped with N-type impurities, that is, the part to form a P-type part 8p of the first layer polysilicon film is coated with a resist film etc. As the conditions on the ion injection at this time, mention is made, for example, of the ion kind of, for example, arsenic, the dose of, for example, about 1×10¹⁵ to 1×10¹⁶ cm⁻², and the injection energy of, for example, about 10 to 100 keV.

Next, as shown in FIG. 25, the first layer polysilicon wiring 12, the first layer polysilicon extraction unit 11, an embedded field plate 31, a peripheral embedded field plate 31p etc., are formed by subjecting about the lower half of the trench 6 to etch back processing as well as patterning the first layer polysilicon films 8n, 8p by dry etching (as the etching gas, mention is made, for example, of SF6 etc.) etc. using a gate processing mask (for example, resist film) etc. patterned by the normal lithography.

Next, as shown in FIG. 26, by performing wet etching using a hydrofluoric acid-based silicon oxide film etching liquid etc., the field plate peripheral insulating film 32 is removed until the upper end part of the field plate electrode 31 and the Si sidewall of the trench 6 are exposed.

Next, as shown in FIG. 27, the gate insulating film 7 (silicon oxide film) having a thickness of about 50 nm is formed by, for example, thermal oxidation etc. At the same time, an insulating film (having a thickness of about 100 nm) between the field plate electrode 31 and the gate electrode is formed. Subsequently, a high concentration phosphorus-doped polysilicon layer 18 (second layer polysilicon film) having a thickness of, for example, about 600 nm, which is to form the N+ trench gate electrode 9 (trench gate polysilicon layer) is formed within the trench 6 and over substantially the entire surface of the device surface 1a of the wafer 1 by, for example, CVD etc.

Next, as shown in FIG. 28, the second layer polysilicon wiring 13, a second layer polysilicon extraction unit 33, the polysilicon gate electrode 9, etc., are formed by performing etch back processing as well as patterning the high concentration phosphorus-doped polysilicon film 8 by dry etching (as the etching gas, mention is made, for example, of SF6 etc.) etc. using a gate processing mask (for example, resist film) etc. patterned by the normal lithography.

Next, as shown in FIG. 29, ions are injected into the part that is to form the P body region 15 (channel region) of the surface 1a of the wafer 1 using a resist film etc. as a mask. As the conditions on the ion injection at this time, mention is made, for example, of the ion kind of, for example, boron, the dose of, for example, about 1×10¹² to 5×10¹³ cm⁻², and the injection energy of, for example, about 50 to 200 keV.

Next, as shown in FIG. 30, the N-type source region 16, the N-type channel stop region 17, the N-type high concentration region 14n++ (for example, FIGS. 36, 38, 40, and 42) of the ESD (Electro-Static Discharge) protection polysilicon Zener diode of the gate protection element 14, etc., are formed by performing ion injection using a resist film etc. as a mask. As the conditions on the ion injection at this time, mention is made, for example, of the ion kind of, for example, arsenic, the dose of, for example, about 1×10¹⁵ to 1×10¹⁶ cm⁻² and the injection energy of, for example, about 10 to 150 keV.

Next, as shown in FIG. 31, by performing additional ion injection using a resist film etc. as a mask, the part into which ions are injected additionally forms the P-type high concentration region 14p++ (for example, FIG. 36 and FIG. 43) of the ESD protection polysilicon Zener diode of the gate protection element 14 and the part of the P-type part into which ions are not injected additionally forms the P-type intermediate concentration region 14p+ (for example, FIG. 36 and FIG. 43). As the conditions on the ion injection at this time, mention is made, for example, of the ion kind of, for example, boron, the dose of, for example, about 1.5×10¹⁵ to 2×10¹⁶ cm⁻², and the injection energy of, for example, about 10 to 150 keV.

Next, as shown in FIG. 32, over substantially the entire surface of the surface 1a of the wafer 1, the interlayer insulating film 19 (having a thickness of, for example, about 250 to 450 nm), such as a PSG film, is formed by, for example, CVD etc. It is preferable for the interlayer insulating film 19 to include a silicon oxide-based insulating film as a principal element and in addition to the PSG film, a single film, such as a BPSG film, a compound film of the BPSG film and an SOG (Spin-On-Glass) film or TEOS film, etc., are also preferable. Next, the contact hole 21, the coupling via 22, etc., are formed by forming a pattern, such as a resist film, over the surface 1a of the wafer 1 by the normal lithography and performing anisotropic dry etching using the pattern as a mask. After that, the resist film etc. that are no longer necessary are removed.

Next, as shown in FIG. 33, the contact hole 21, the coupling via 22, etc., are extended downward (for example, about 0.35 μm) by performing anisotropic dry etching (silicon etching) using the interlayer insulating film 19 as a mask. Subsequently, the P-type body contact region 23 and the P-type peripheral contact region 24 are introduced by performing ion injection through the contact hole 21 in the state where unnecessary parts are coated with a resist film etc. As the conditions on the ion injection at this time, mention is made, for example, of the ion kind of, for example, boron (or BF₂), the dose of, for example, about 1×10¹⁵ to 5×10¹⁶ cm⁻², and the injection, energy of, for example, about 20 to 200 keV.

Next, as shown in FIG. 34, on the inner surface of the contact hole 21 and substantially the entire surface of the device surface 1a of the wafer 1, for example, an aluminum-based source metal film (having a thickness of, for example, about 3.5 to 5.5 μm) including aluminum as a principal component (for example, several percent of added silicon and the rest is aluminum) is formed by, for example, sputtering deposition. Subsequently, the metal source electrode or the source pad 26 (or source terminal), the metal gate electrode 27 (gate pad or gate terminal), the metal guard ring 28, etc., are formed by patterning a source metal electrode including an aluminum-based source metal film and a barrier metal film by the normal lithography.

After that, according to the necessity, an organic film (having a thickness of, for example, about 2.5 μm) etc. including polyimide as a principal component is applied to substantially the entire surface of the device surface 1a of the wafer 1 as a final passivation film. Next, by the normal lithography, the final passivation film at the part corresponding to the source pad opening, the gate pad opening, is removed.

Next, by subjecting the back surface 1b of the wafer 1 to back grinding processing, the wafer having a thickness f, for example, about 500 to 900 μm is thinned to the wafer having a thickness of, for example, about 300 to 30 μm if necessary. After that, the back surface electrode 29 is formed by, for example, sputtering deposition. Further, by dicing etc., the wafer 1 is divided into individual chips 2.

The embedded field plate 31 (peripheral embedded field plate) is electrically coupled to the same potential as that of the source electrode or gate electrode by the metal layer in the same layer as that of the metal source electrode 26 or the metal gate electrode 27. When coupled to the source electrode, the gate capacitance is reduced and suitable for use for high speed switching etc. On the other hand, when coupled to the gate electrode, there is an advantage that the insulating film between the embedded field plate 31 and the intrinsic gate 9 can be thinned (manufacturing is facilitated).

7. Explanation of the Device Structure of an IGBT, which is Another Example of the Insulating Gate Power Transistor in the Semiconductor Device in the Embodiment of the Present Application, and the Gate Protection Element (One-Dimensional Multi-Concentration Type) (Mainly see FIG. 35, FIG. 1, and FIG. 3)

In this section, a specific example of a case where the insulating gate power transistor is an N-channel type punch through IGBT is explained using an example in which the top surface layout is substantially the same as that in FIG. 1 and the structure of the gate protection element 14 is substantially the same as that in FIG. 3. However, it is needless to say that as to the structure etc. of the gate protection element 14, the other examples shown in the present application can be applied with no modification. Similarly, it is needless to say that in the case of the non-punch through IGBT, they can also be applied with almost no modification.

FIG. 35 is a device schematic section view of a device chip including a device structure of IGBT, which is another example of the insulating gate power transistor corresponding to FIG. 2 in the semiconductor device in the embodiment of the present application, and a gate protection element (one-dimensional multi-concentration type). Based on these (see FIG. 1 and FIG. 3), the device structure of IGBT, which is another example of the insulating gate power transistor in the semiconductor device in the embodiment of the present application, and the gate protection element (one-dimensional multi-concentration type) are explained.

As shown in FIG. 35, on the outermost circumference of the surface 1a of the semiconductor chip 2 (semiconductor substrate 1), the annular metal guard ring 28 (for example, an aluminum-based metal guard ring etc.) is provided and inside thereof, the annular N-type channel stop region 17 (region introduced at the same time as the N-type source region 16, that is, an emitter region) is provided. Further, inside thereof, the one, two, or more field limiting rings 5 or floating field rings are provided and at the chip center part inside the field limiting ring 5, the cell region 36 is provided. The P well region 4 in the form of a somewhat complicated annulus is embedded between the field limiting ring 5 and the cell region 36 and the peripheral part of the cell region 36 is the buffer region 37 having a structure different from that of the inner region. The outside thereof is the chip peripheral region 38 with the buffer region 37 sandwiched in between.

The cell region 36 and the buffer region 37 are provided with the trenches 6 (FIG. 1) in the form of a mesh and a trench gate electrode in the form of a comparatively thin slab, that is, the polysilicon gate electrode 9 (for example, the first layer polysilicon film 8) is embedded therein via the gate insulating film 7. The polysilicon gate electrode 9 is extracted outside the trench 6 by the first layer polysilicon extraction unit 11 and coupled to the metal gate wiring 39 (FIG. 1) at the part of the first layer polysilicon wiring 12 on the periphery via the metal & polysilicon coupling hole 41 (FIG. 1) and reaches the metal gate electrode 27 (gate pad).

In the cell region 36, in the active region 40 (part other than the trench in the cell region) between the trenches 6 in the form of a mesh, the P-type body contact region 23 is provided and on the periphery thereof, the N-type source region 16 (also called an emitter region in the case of IGBT) is provided. To the P-type body contact region 23, the metal source electrode 26 (source pad or emitter pad) is coupled and the gate protection element 14 is coupled to the metal gate electrode 27 (gate terminal) via the gate side contact part 20g and to the metal source electrode 26 (source terminal) via the source side contact part 20s.

The collector layer is on the back surface of the chip 2 is, for example, a comparatively high concentration P-type silicon region and on the side of the back surface 1b, the drain metal electrode 29 (also called a collector electrode in the case of IGBT) is provided. On the side of the surface of the collector layer is, the comparatively lower concentration N-type silicon epitaxy layer 1e (drift region 10) is provided and between the N-type drift region 10 and the collector layer is, the N-type buffer layer 34 (field stop layer) higher in concentration than the N-type drift region 10 is provided.

In the chip peripheral region 38 of the surface region of the N-type silicon epitaxy layer 1e, the P well regions 4, 5 and the P-type peripheral contact region 24 (formed at the same time as, for example, the P-type body contact region 23) are provided. On the other hand, across the entire surface of the cell region 36 and the periphery thereof of the surface region of the N-type silicon epitaxy layer 1e, the P body region 15 (P-type body region) constituting the channel region is formed. Over the surface of the N-type silicon epitaxy layer 1e of the chip peripheral region 38, the field insulating film 3 is formed and the interlayer insulating film 19 is formed thereover. Within the trench in the buffer region 37, the peripheral dummy polysilicon gate electrode 9p is provided to prevent deterioration in withstand voltage on the periphery of the cell region 36.

The manufacturing method is basically the same as that in the section 5 and in general, a wafer having substantially the same impunity concentration as that of the N-type silicon epitaxy layer 1e is provided and after forming the device structure on the side of the surface, the N-type buffer layer 34 and the collector layer is are introduced by ion injection from the back surface after back grinding.

8. Summary

The invention made by the inventors of the present invention is explained specifically based on the embodiments, however, it is needless to say that the present invention is not limited to those and there can be various modifications in the scope not deviating from its gist.

For example, in the embodiments, the N-channel type device is specifically explained mainly, however, it is needless to say that the present invention is not limited to that and the embodiments can also be applied to a P-channel type device with almost no modification.

Further, in the embodiments, the single device is specifically explained mainly, however, it is needless to say that the present invention is not limited to that and the embodiments can also be applied to a compound semiconductor chip (semiconductor device) that incorporates the insulating gate power transistor with almost no modification.

Furthermore, in the embodiments, the silicon-based device is specifically explained mainly, however, it is needless to say that the present invention is not limited to that and the embodiments can also be applied to a device that uses a substrate material belonging to another group, such as a Si-based device and a SiN-based device.

In the embodiments, the device that uses the electrode (aluminum-based electrode) including the metal layer containing aluminum as a principal component as a principal component is explained specifically as the surface side metal, however, it is needless to say that the present invention is not limited to that and the embodiments can also be applied to a device that uses another electrode metal, such as a tungsten-based electrode, with almost no modification.

What is claimed is:

1. A semiconductor device, comprising:
(a) a semiconductor chip;
(b) an insulating gate power transistor formed on the semiconductor chip; and
(c) a gate protection element formed in the semiconductor chip and coupled between a gate terminal and a source terminal of the insulating gate power transistor,
the gate protection element including a bidirectional Zener diode having a multistage PN junction,
wherein the bidirectional Zener diode has
the withstand voltage with its gate terminal side negatively biased and the withstand voltage with the gate terminal side positively biased, different from each other, and
wherein the bidirectional Zener diode includes:
(x1) a source side first conductivity type region;
(x2) a gate side first conductivity type region having substantially the same impurity concentration as that of the source side first conductivity type region and formed in a part nearer to the gate terminal in a circuit; and
(x3) a second conductivity type region coupled in series between the source side first conductivity type region and the gate side first conductivity type region, forming a source side PN junction between the source side first conductivity type region and itself, and forming a gate side PN junction between the gate side first conductivity type region and itself, the second conductivity type region having concentrations different from each other in both end parts thereof.

2. The semiconductor device according to claim 1,
wherein when the insulating gate power transistor is an N-channel type, the bidirectional Zener diode has the withstand voltage with its gate terminal side negatively biased set lower compared to that with the gate terminal side positively biased, and when the insulating gate power transistor is a P-channel type, the bidirectional Zener diode has the withstand voltage with the gate terminal side positively biased set lower compared to that with the gate terminal side negatively biased.

3. The semiconductor device according to claim 2,
wherein a piece of polysilicon film comprises the bidirectional Zener diode.

4. The semiconductor device according to claim 3,
wherein the polysilicon film constituting the bidirectional Zener diode is formed in a layer different from the layer in which a polysilicon film constituting polysilicon intrinsic gate electrode of the insulating gate power transistor is formed.

5. The semiconductor device according to claim 4,
wherein both end parts of the bidirectional Zener diode are N-type regions.

6. The semiconductor device according to claim 5,
wherein the bidirectional Zener diode is a one-dimensional type.

7. The semiconductor device according to claim 5,
wherein the bidirectional Zener diode is a two-dimensional type and each region constituting the bidirectional Zener diode has a rounded planar shape.

8. The semiconductor device according to claim 7,
wherein the second conductivity type region includes two regions having different concentrations.

9. The semiconductor device according to claim 8,
wherein the insulating gate power transistor is an insulating gate power MOSFET.

10. The semiconductor device according to claim 8,
wherein the insulating gate power transistor is an IGBT.

11. A semiconductor device comprising:
(a) a semiconductor chip;
(b) an insulating gate power transistor formed in the semiconductor chip; and
(c) a gate protection element formed in the semiconductor chip and coupled between a gate and a source of the insulating gate power transistor, the gate protection element having the withstand voltage with its gate side negatively biased and the withstand voltage with the gate side positively biased, different from each other,
the gate protection element including:
(x1) a bidirectional Zener diode having a multistage PN junction; and
(x2) another Zener diode coupled in series between the gate and the source with an ohmic wiring together with the bidirectional Zener diode.

12. The semiconductor device according to claim 11,
wherein when the insulating gate power transistor is an N-channel type, the gate protection element has the withstand voltage with its gate terminal side negatively biased set lower compared to that with the gate terminal side positively biased, and when the insulating gate power transistor is a P-channel type, the gate protection element has the withstand voltage with its gate terminal side positively biased set lower compared to that with the gate terminal side negatively biased.

13. The semiconductor device according to claim 12,
wherein the regions of the bidirectional Zener diode and the another Zener diode interconnected to each other with the ohmic wiring are separated from each other.

14. The semiconductor device according to claim 12,
wherein the regions of the bidirectional Zener diode and the another Zener diode interconnected to each other with the ohmic wiring are coupled to each other to form a PN junction.

15. The semiconductor device according to claim 14,
wherein the bidirectional Zener diode and the another Zener diode are formed in the same single layer polysilicon film.

16. The semiconductor device according to claim 15,
wherein the polysilicon film constituting the bidirectional Zener diode and the another Zener diode is formed in a layer different from the layer in which a polysilicon film constituting a polysilicon intrinsic gate electrode of the insulating gate power transistor is formed.

17. The semiconductor device according to claim 16,
wherein the bidirectional Zener diode is a one-dimensional type.

18. The semiconductor device according to claim 16,
wherein the bidirectional Zener diode is a two-dimensional type and each region constituting the bidirectional Zener diode has a rounded planar shape.

19. The semiconductor device according to claim 18,
wherein the insulating gate power transistor is an insulating gate power MOSFET.

20. The semiconductor device according to claim 18,
wherein the insulating gate power transistor is an IGBT.
